(19) United States
(12) Patent Application Publication
(10) Pub. No.: US 2026/0190367 A1
(43) Pub. Date: Jul. 2, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Hong-Chih CHEN, Changhua County (TW); Ta-Chun LIN, Hsinchu (TW); Chih-Hao CHANG, Chu-Bei City (TW); Jhon-Jhy LIAW, Zhudong Township (TW)

(21) Appl. No.: 19/002,151

(22) Filed: Dec. 26, 2024

(51) Int. Cl. H10D 30/01; H10D 30/00

(52) U.S. Cl. CPC H10D 30/0191; H10D 30/502

(57) ABSTRACT

A method for forming a semiconductor structure is provided. The method includes forming an active region including a plurality of channel layers and a cap layer above the plurality of channel layers, forming a source/drain feature adjoining the channel layers of the active region, forming a gate stack to wrap around the channel layers and the cap layer of the active region, polishing the gate stack at least until the cap layer of the active region is exposed, and forming a contact plug on the source/drain feature.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with related complementary metal-oxide-semiconductor (CMOS) processes, and their structure allows them to be aggressively scaled-down while maintaining gate control and mitigating SCEs. In related processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIGS. 3A-1 and 3A-2 are cross-sectional views illustrating the formation of a semiconductor structure at one of the intermediate stages corresponding to line X1-X1 and line Y1-Y1 of FIG. 2, in accordance with some embodiments of the disclosure.

FIGS. 3B-1 and 3B-2 are cross-sectional views illustrating the formation of a semiconductor structure at one of the intermediate stages corresponding to line X1-X1 and line Y1-Y1 of FIG. 2, in accordance with some embodiments of the disclosure.

FIGS. 3C-1, 3C-2 and 3C-3 are cross-sectional views illustrating the formation of a semiconductor structure at one of the intermediate stages corresponding to line X1-X1, line Y1-Y1 and line Y2-Y2 of FIG. 2, in accordance with some embodiments of the disclosure.

FIGS. 3D-1, 3D-2 and 3D-3 are cross-sectional views illustrating the formation of a semiconductor structure at one of the intermediate stages corresponding to line X1-X1, line Y1-Y1 and line Y2-Y2 of FIG. 2, in accordance with some embodiments of the disclosure.

FIGS. 3E-1 and 3E-2 are cross-sectional views illustrating the formation of a semiconductor structure at one of the intermediate stages corresponding to line X1-X1 and line Y1-Y1 of FIG. 2, in accordance with some embodiments of the disclosure.

FIGS. 3F-1 and 3F-2 are cross-sectional views illustrating the formation of a semiconductor structure at one of the intermediate stages corresponding to line X1-X1 and line Y1-Y1 of FIG. 2, in accordance with some embodiments of the disclosure.

FIG. 3G is a cross-sectional view illustrating the formation of a semiconductor structure at one of the intermediate stages corresponding to line X1-X1 of FIG. 2, in accordance with some embodiments of the disclosure.

FIG. 3H is a cross-sectional view illustrating the formation of a semiconductor structure at one of the intermediate stages corresponding to line X1-X1 of FIG. 2, in accordance with some embodiments of the disclosure.

FIGS. 31-1 and 31-2 are cross-sectional views illustrating the formation of a semiconductor structure at one of the intermediate stages corresponding to line X1-X1 and line Y2-Y2 of FIG. 2, in accordance with some embodiments of the disclosure.

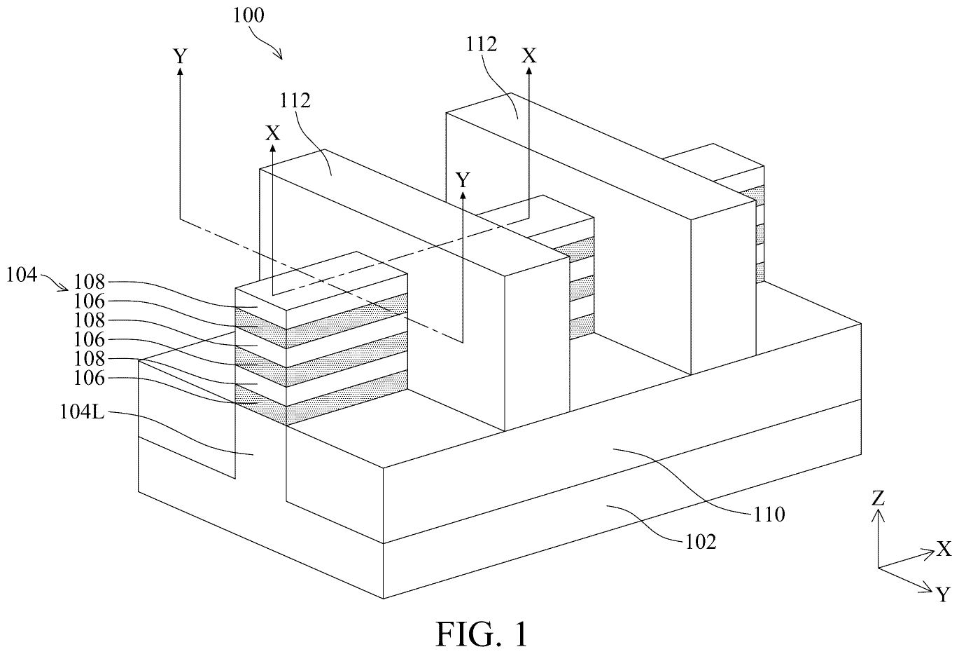

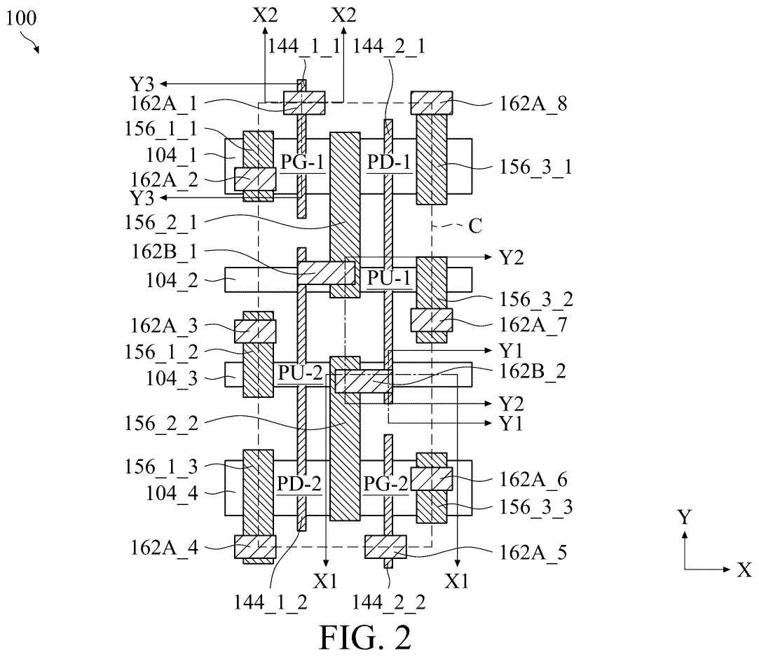

FIGS. 3J-1 and 3J-2 are cross-sectional views illustrating the formation of a semiconductor structure at one of the intermediate stages corresponding to line X1-X1 and line Y2-Y2 of FIG. 2, in accordance with some embodiments of the disclosure.

FIGS. 3K-1 and 3K-2 are cross-sectional views illustrating the formation of a semiconductor structure at one of the intermediate stages corresponding to line X1-X1 and line Y1-Y1 of FIG. 2, in accordance with some embodiments of the disclosure.

FIGS. 3L-1, 3L-2 and 3L-3 are cross-sectional views illustrating the formation of a semiconductor structure at one of the intermediate stages corresponding to line X1-X1, line Y1-Y1 and line Y2-Y2 of FIG. 2, in accordance with some embodiments of the disclosure.

FIGS. 3M-1, 3M-2 and 3M-3 are cross-sectional views illustrating the formation of a semiconductor structure at one of the intermediate stages corresponding to line X1-X1, line Y1-Y1 and line Y2-Y2 of FIG. 2, in accordance with some embodiments of the disclosure.

FIGS. 3N-1, 3N-2 and 3N-3 are cross-sectional views illustrating the formation of a semiconductor structure at one of the intermediate stages corresponding to line X1-X1, line Y1-Y1 and line Y2-Y2 of FIG. 2, in accordance with some embodiments of the disclosure.

FIGS. 3O-1, 3O-2, 3O-3, 3O-4 and 3O-5 are cross-sectional views illustrating the formation of a semiconductor structure at one of the intermediate stages corresponding to line X1-X1, line Y1-Y1, line Y2-Y2, line X2-X2 and line Y3-Y3 of FIG. 2, in accordance with some embodiments of the disclosure.

FIGS. 3P-1, 3P-2, 3P-3, 3P-4 and 3P-5 are cross-sectional views illustrating the formation of a semiconductor structure at one of the intermediate stages corresponding to line X1-X1, line Y1-Y1, line Y2-Y2, line X2-X2 and line Y3-Y3 of FIG. 2, in accordance with some embodiments of the disclosure.

FIGS. 4A-1 and 4A-2 are cross-sectional views illustrating the formation of a semiconductor structure at one of the intermediate stages corresponding to line X1-X1 and line Y1-Y1 of FIG. 2, in accordance with some embodiments of the disclosure.

FIGS. 4B-1 and 4B-2 are cross-sectional views illustrating the formation of a semiconductor structure at one of the intermediate stages corresponding to line X1-X1 and line Y1-Y1 of FIG. 2, in accordance with some embodiments of the disclosure.

FIGS. 5A-1 and 5A-2 are cross-sectional views illustrating the formation of a semiconductor structure at one of the intermediate stages corresponding to line X1-X1 and line Y1-Y1 of FIG. 2, in accordance with some embodiments of the disclosure.

FIGS. 5B-1 and 5B-2 are cross-sectional views illustrating the formation of a semiconductor structure at one of the intermediate stages corresponding to line X1-X1 and line Y1-Y1 of FIG. 2, in accordance with some embodiments of the disclosure.

FIGS. 6-1 and 6-2 are cross-sectional views illustrating a semiconductor structure corresponding to line X1-X1 and line Y1-Y1 of FIG. 2, in accordance with some embodiments of the disclosure.

FIGS. 7-1 and 7-2 are cross-sectional views illustrating a semiconductor structure corresponding to line X1-X1 and line Y1-Y1 of FIG. 2, in accordance with some embodiments of the disclosure.

FIGS. 8-1 and 8-2 are cross-sectional views illustrating a semiconductor structure corresponding to line X1-X1 and line Y1-Y1 of FIG. 2, in accordance with some embodiments of the disclosure.

FIG. 9 is a cross-sectional view illustrating a semiconductor structure corresponding to line X1-X1 of FIG. 2, in accordance with some embodiments of the disclosure.

FIGS. 10-1 and 10-2 are cross-sectional views illustrating a semiconductor structure corresponding to line X1-X1 and line Y1-Y1 of FIG. 2, in accordance with some embodiments of the disclosure.

FIGS. 11-1 and 11-2 are cross-sectional views illustrating a semiconductor structure corresponding to line X-X and line Y-Y of FIG. 1, in accordance with some embodiments of the disclosure.

FIGS. 12-1 and 12-2 are cross-sectional views illustrating a semiconductor structure corresponding to line X-X and line Y-Y of FIG. 1, in accordance with some embodiments of the disclosure.

FIGS. 13-1 and 13-2 are cross-sectional views illustrating a semiconductor structure corresponding to line X-X and line Y-Y of FIG. 1, in accordance with some embodiments of the disclosure.

FIGS. 14-1 and 14-2 are cross-sectional views illustrating a semiconductor structure corresponding to line X-X and line Y-Y of FIG. 1, in accordance with some embodiments of the disclosure.

FIGS. 15-1 and 15-2 are cross-sectional views illustrating a semiconductor structure corresponding to line X-X and line Y-Y of FIG. 1, in accordance with some embodiments of the disclosure.

FIGS. 16-1 and 16-2 are cross-sectional views illustrating a semiconductor structure corresponding to line X-X and line Y-Y of FIG. 1, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and a method for forming the semiconductor structure are provided. The method includes forming a gate electrode layer to wrap around a plurality of channel layers and a fin cap layer over the channel layers, and polishing the gate electrode layer at least until the fin cap layer is exposed. Each of the channel layers is vertically sandwiched between inner gate electrodes, each of which may have substantially the same configuration and symmetry of the gate materials. Therefore, the performance, stability, and reliability of the resulting semiconductor device may be improved (e.g., variation of threshold voltage).

FIG. 1 is a perspective view of a semiconductor structure 100, in accordance with some embodiments of the disclosure.

The semiconductor structure 100 includes a substrate 102 and a fin structure 104 and an isolation structure 110 over the substrate 102, as shown in FIG. 1, in accordance with some embodiments. For a better understanding of the semiconductor structure 100, the X-Y-Z coordinate reference is provided in the figures of the present disclosure. The X-axis and the Y-axis are generally orientated along the lateral (or horizontal) directions that are parallel to the main surface (e.g., top surface) of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104 includes a lower fin element 104L surrounded by the isolation structure 110, and an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

The fin structure 104 extends in the X direction, in accordance with some embodiments. That is, the fin structure 104 has a longitudinal axis parallel to the X direction, in accordance with some embodiments. The X direction may also be referred to as the channel direction. The current of the resulting semiconductor device (i.e., nanostructure transistor) flows in the X direction through the channel. The fin structure 104 is defined as several channel regions and several source/drain regions, where the channel regions and the source/drain regions are alternately arranged, in accordance with some embodiments. It is noted that in the present disclosure, source/drain region(s) or source/drain feature(s) may refer to a source or a drain, individually or collectively dependent upon the context.

Gate structures 112 are formed with longitudinal axes parallel to the Y direction and extending across and/or surrounding the channel regions of the fin structure 104, in accordance with some embodiments. The source/drain regions of the fin structure 104 are exposed from the gate structures 112, in accordance with some embodiments. The Y direction may also be referred to as a gate-routing direction, in accordance with some embodiments.

FIG. 1 further illustrates reference cross-sections that are used in later figures (FIGS. 11-1 through 16-2), in accordance with some embodiments. Cross-section X-X is in a plane parallel to the longitudinal axis (X direction) of a fin structure 104 and through the fin structure 104. Cross-section Y-Y is in a plane parallel to the longitudinal axis (Y direction) of a gate structure 112 (or a final gate stack) and through the gate structure 112 (or a final gate stack).

FIG. 2 is a layout of a semiconductor structure 100, in accordance with some embodiments. The semiconductor structure 100 includes an SRAM (static random access memory) cell region C, in accordance with some embodiments. In some other embodiments, the semiconductor structure 100 may further include other device regions such as a logic device region, an analog region, a peripheral region, and/or a combination thereof, in accordance with some embodiments.

The SRAM cell region C is formed by active regions 104 (including 104_1, 104_2, 104_3 and 104_4) and gate stacks 144 (including 144_1 and 144_2). The active region 104_1 is formed in a p-type well (not shown), the active regions 104_2 and 104_3 are formed in an n-type well (not shown), and the active region 104_4 is formed in another p-type well (not shown), in accordance with some embodiments.

The active regions 104_1 to 104_4 are the fin structures 104 as shown in FIG. 1. Each of the active regions 104_1 to 104_4 includes a lower fin element and sets of nanostructures over the lower fin element, in accordance with some embodiments. As the term is used herein, “nanostructures” refers to active regions of a semiconductor structure that includes multiple semiconductor layers with cylindrical shape, bar shape and/or sheet shape. The lower fin elements of the active regions 104 extend in the X direction (row direction), in accordance with some embodiments.

The gate stacks 144_1 and 144_2 extend in the Y direction (column direction) across the lower fin elements and wrap around the nanostructures, in accordance with some embodiments. In some embodiments, each of the gate stacks 144_1 and 144_2 may include several segments electrically and physically isolated from each other, in accordance with some embodiments. For example, the gate stack 144_1 includes gate stacks 144_1_1 and 144_1_2, and the gate stack 144_2 includes gate stacks 144_2_1 and 144_2_2.

In some embodiments, the SRAM cell region C includes the six functional transistors PG-1 and PG-2, PD-1 and PD-2 and PU-1 and PU-2 which are nanostructure transistors. A pull-up transistor PU-1 and a pull-down transistor PD-1 form a first inverter, and a pull-up transistor PU-2 and a pull-down transistor PD-2 form a second inverter. The first and second inverters are cross-coupled to form a latch. In some embodiments, the pass-gate transistors PG-1 and PG-2 and the pull-down transistors PD-1 and PD-2 are n-channel nanostructure transistors, and the pull-up transistors PU-1 and PU-2 are p-channel nanostructure transistors.

The pass-gate transistor PG-1 is formed at the cross point of the active region 104 1 and the gate stack 144_1_1, the pull-down transistor PD-1 is formed at the cross point of the active region 104_1 and the gate stack 144_2_1, and the pull-up transistor PU-1 is formed at the cross point of the active region 104_2 and the gate stack 144_2_1. The pass-gate transistor PG-2 is formed at the cross point of the active region 104_4 and the gate stack 144_2_2, the pull-down transistor PD-2 is formed at the cross point of the active region 104_4 and the gate stack 144_1_2, and the pull-up transistor PU-2 is formed at the cross point of the active region 104_3 and the gate stack 144_1_2. In addition, no functional transistors are formed at the cross point of the active regions 104_2 and the gate stack 144_1_2 and at the cross point of the active regions 104_3 and the gate stack 144_2_1.

Various contact plugs 156 (including 156_1, 156_2 and 156_3) and their corresponding interconnect vias 162 (including 162A and 162B) may be employed to electrically connect components in SRAM cell region C. The contact plug 156_1, 156_2 and 156_3 extend in the Y direction (column direction) across the source/drain regions of the active regions 104_1 to 104_4, in accordance with some embodiments. In some embodiments, each of the contact plugs 156_1, 156_2 and 156_3 may include several segments electrically and physically isolated from each other, in accordance with some embodiments. For example, the contact plug 156_1 includes contact plugs 156_1_1, 156_1_2 and 156 1_3, the contact plugs 156_2 includes contact plugs 156_2_1 and 156_2_2, and the contact plug 156_3 includes contact plugs 156_3_1, 156_3_2 and 156_3_3.

In some embodiments, a bit line (BL) (not shown) may be electrically connected to the source terminal of the pass-gate transistor PG-1 through the contact plug 156_1_1 and a via 162A_2 thereon, and a complementary bit line (BLB) (not shown) may be electrically connected to the source terminal of the pass-gate transistor PG-2 through the contact plug 156_3_3 and a via 162A_6 thereon.

A power supply node VDD (not shown) may be electrically connected to the source terminal of the pull-up transistor PU-1 through the contact plug 156_3_2 and a via 162A_7 thereon, and electrically connected to the source terminal of the pull-up transistor PU-2 through the contact plug 156_1_2 and a via 162A 3 thereon.

A ground VSS (not shown) may be electrically connected to the source terminal of the pull-down transistor PD-1 through the contact plug 156_3_1 and a via 162A 8 thereon, and electrically connected to the source terminal of the pull-down transistor PD-2 through the contact plug 156_1_3 and a via 162A 4 thereon.

The drain terminals of the pull-up transistor PU-1 and the pull-down transistor PD-1 may be electrically connected to each other through the contact plug 156_2_1, and further electrically connected to the gate terminals of the pull-up transistor PU-2 and the pull-down transistor PD-2 through a via 162B_1. The drain terminals of the pull-up transistor PU-2 and the pull-down transistor PD-2 may be electrically connected to each other through the contact plug 156_2_2, and further electrically connected to the gate terminals of the pull-up transistor PU-1 and the pull-down transistor PD-1 through a via 162B 2. The via 162B_1 and 162B_2 are also referred to as butt contacts.

FIG. 2 further illustrates reference cross-sections that are used in later figures (FIG. 3A-1 through 10-2), in accordance with some embodiments. Cross-section X1-X1 is in a plane parallel to the longitudinal axis (X direction) of an active region 104 and through the active region 104_3. Cross-section X2-X2 is in a plane parallel to the longitudinal axis (X direction) of an active region 104 and through an isolation structure. Cross-section Y1-Y1 is in a plane parallel to the longitudinal axis (Y direction) of a gate stack 144 and through the gate stack 144_2_1. Cross-section Y2-Y2 is in a plane parallel to the longitudinal axis (Y direction) of a gate stack 144 and across the source/drain regions (e.g., drain terminal) of the active regions 104_2 and 104_3. Cross-section Y3-,15 Y3 is in a plane parallel to the longitudinal axis (Y direction) of a gate stack 144 and through the gate stack 144_1_1.

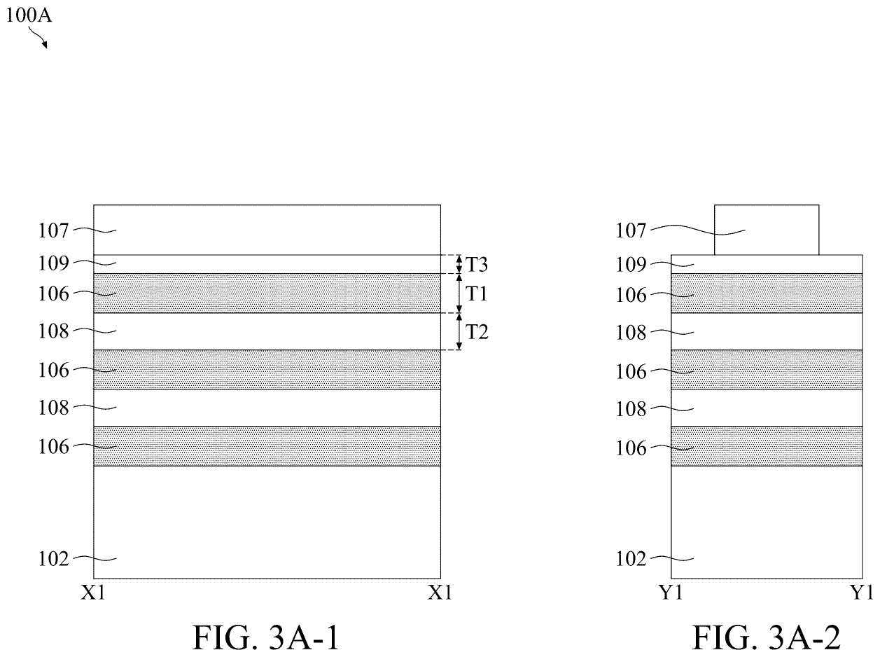

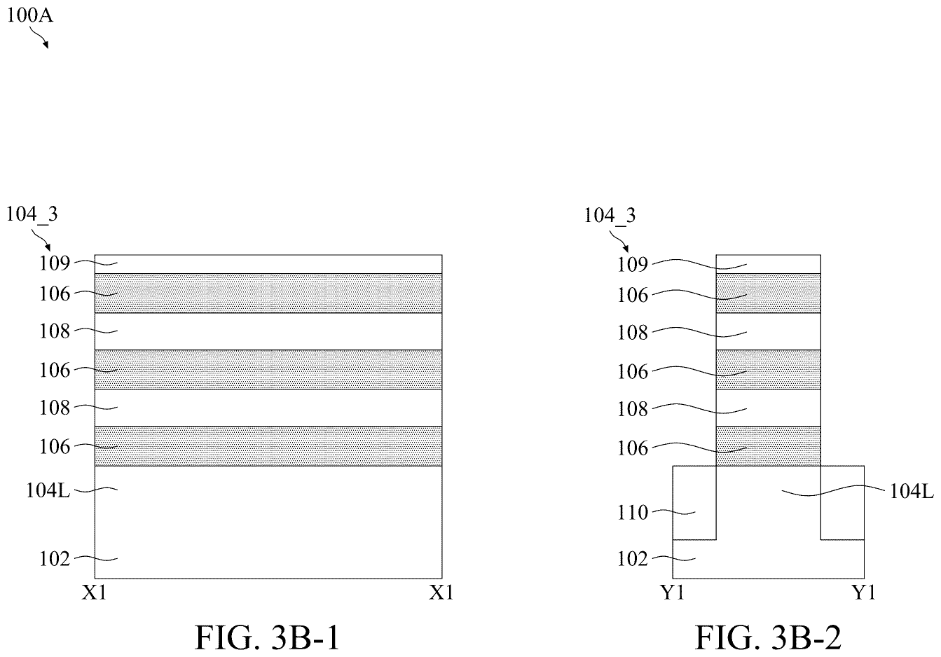

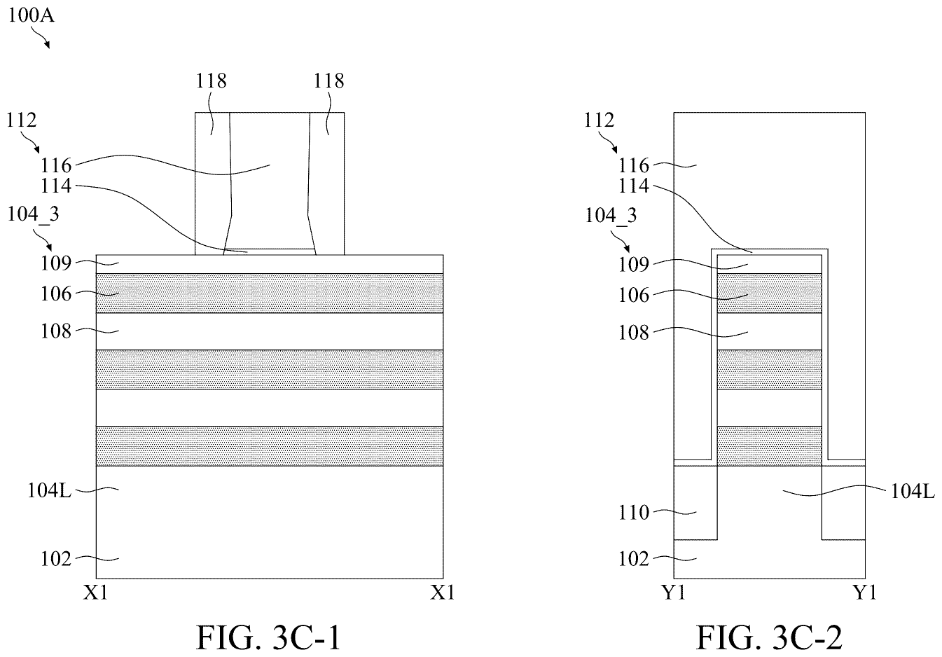

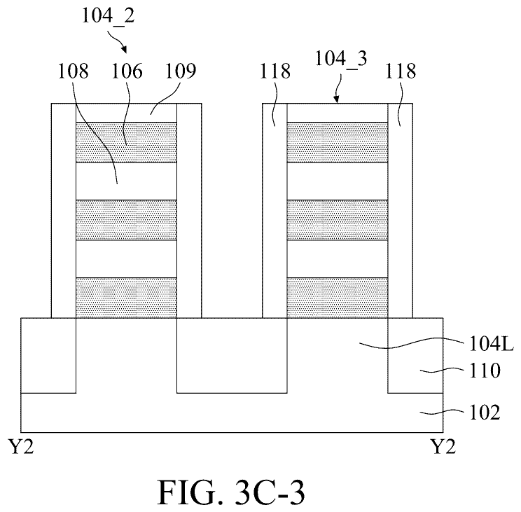

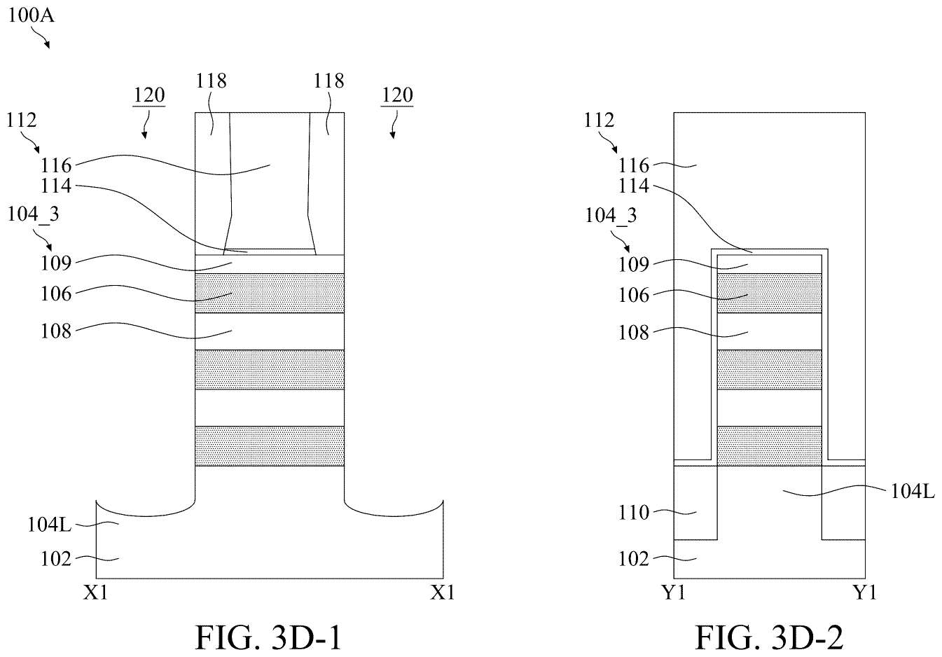

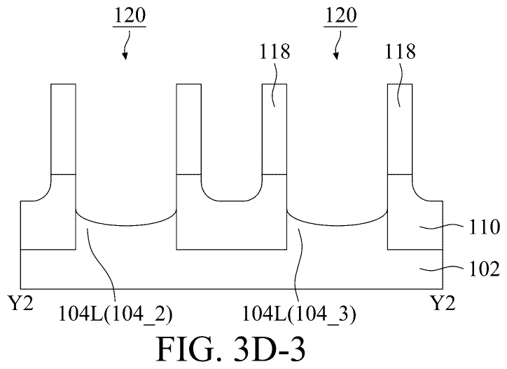

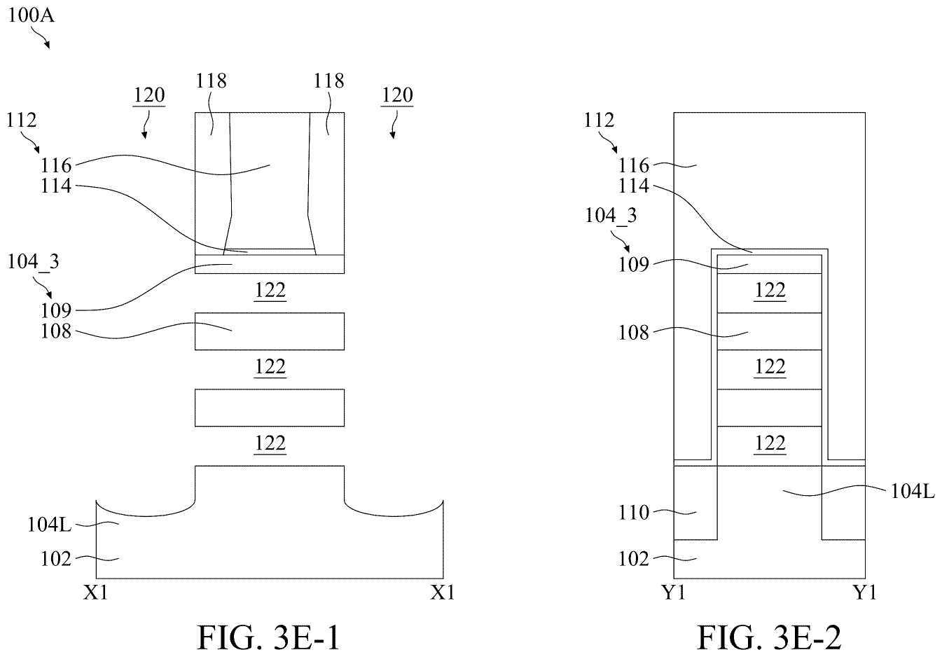

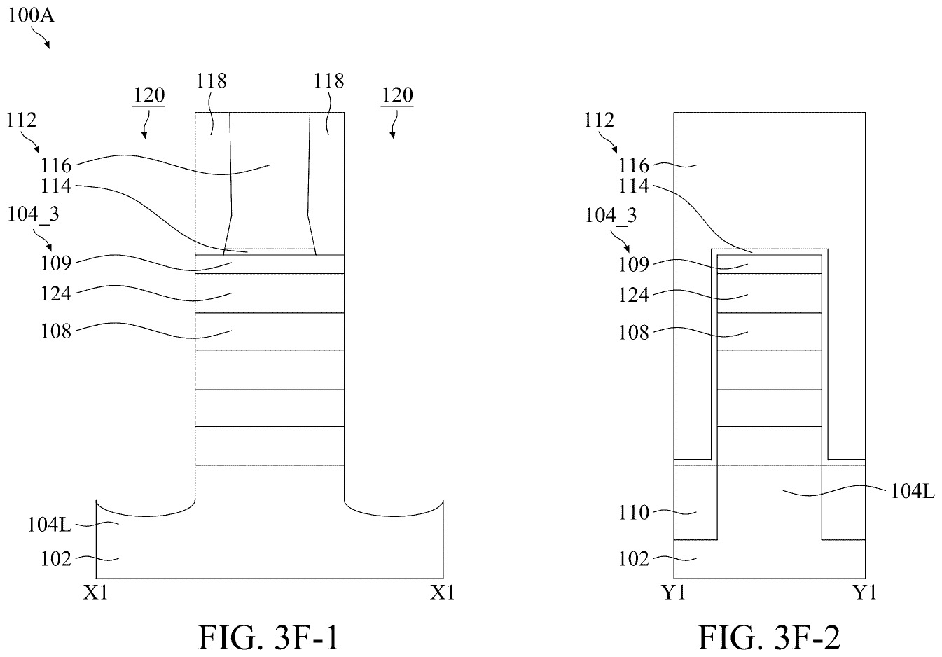

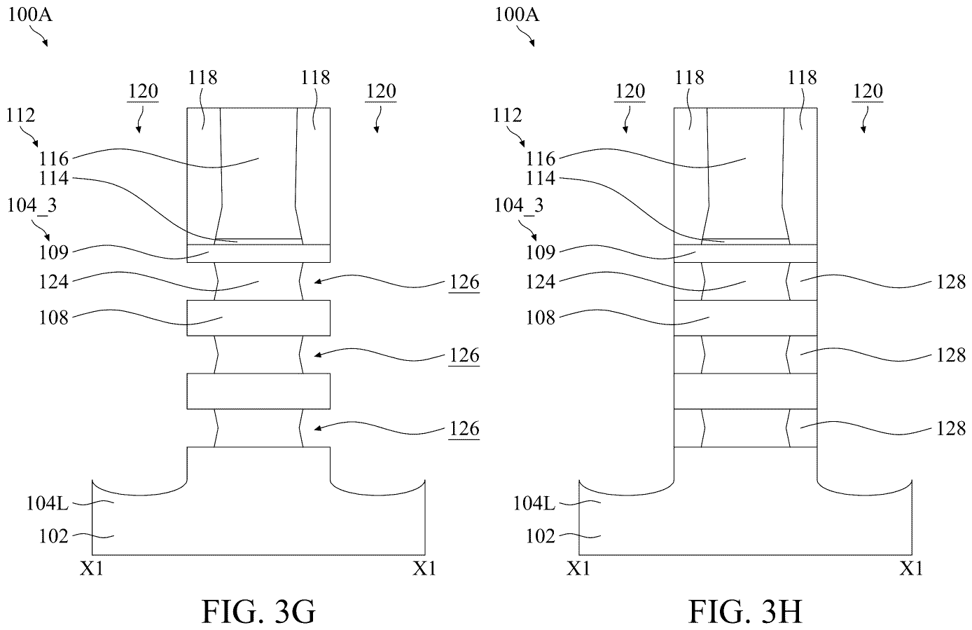

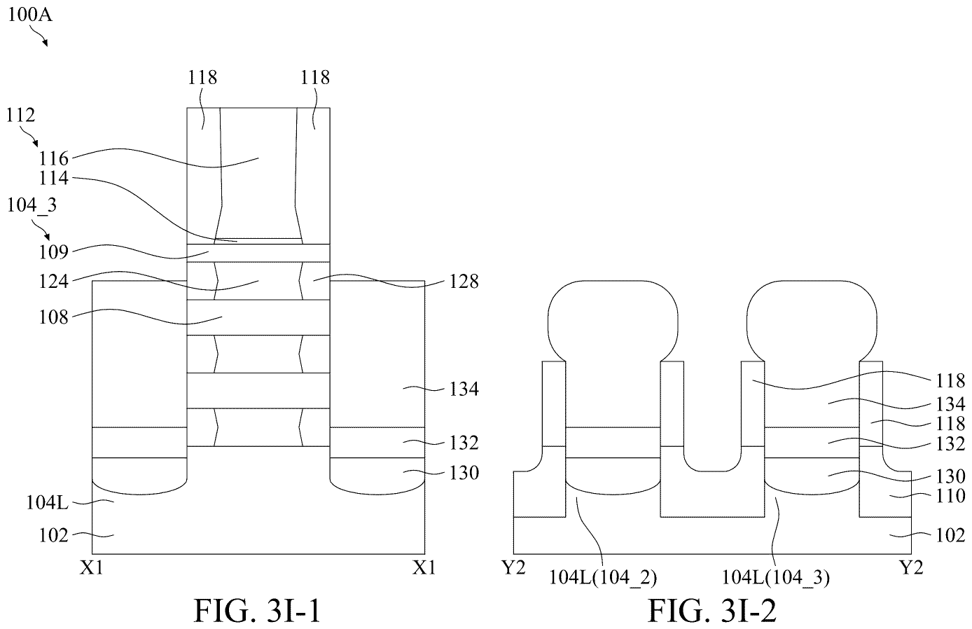

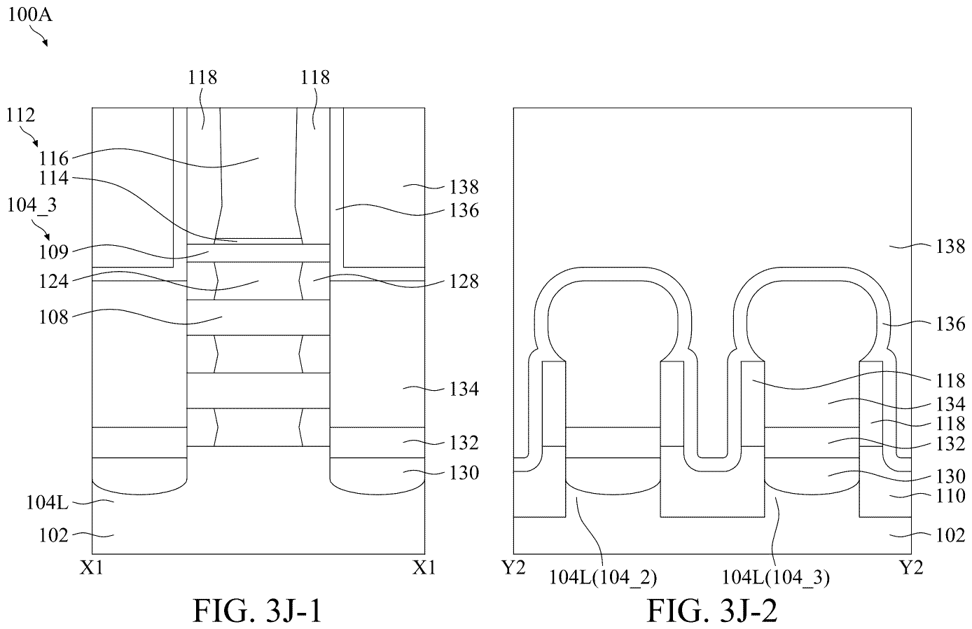

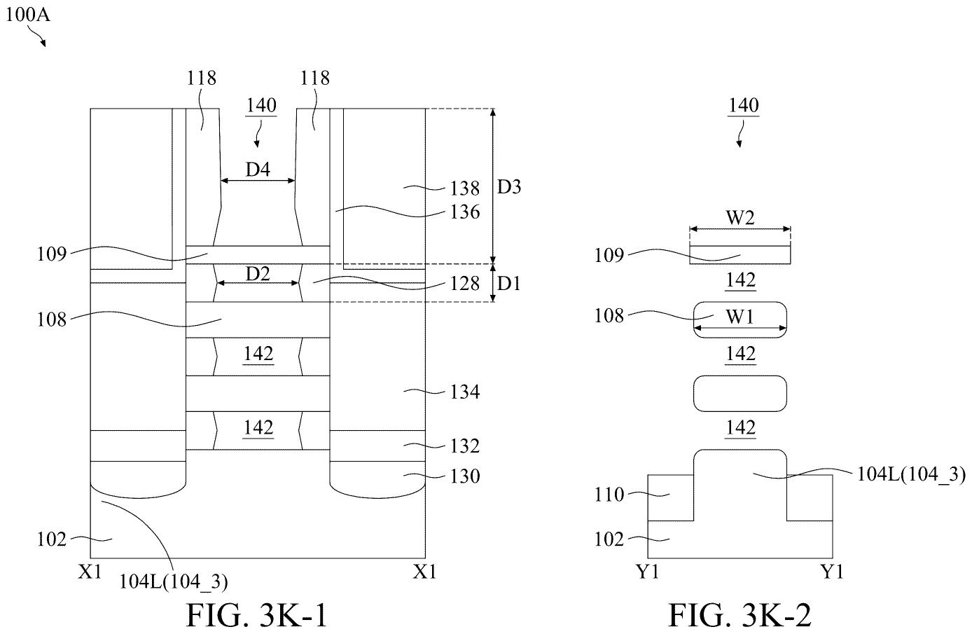

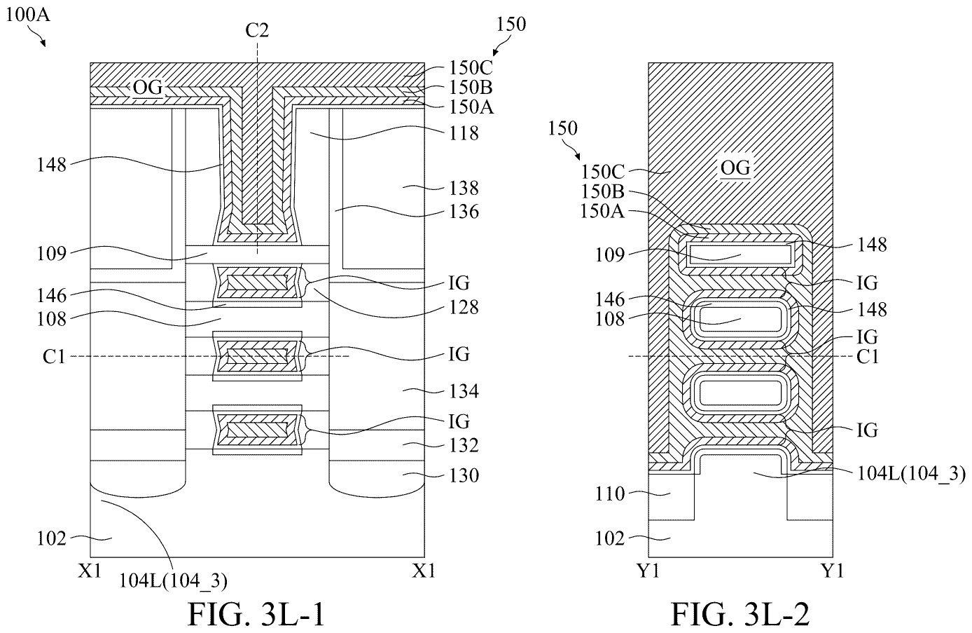

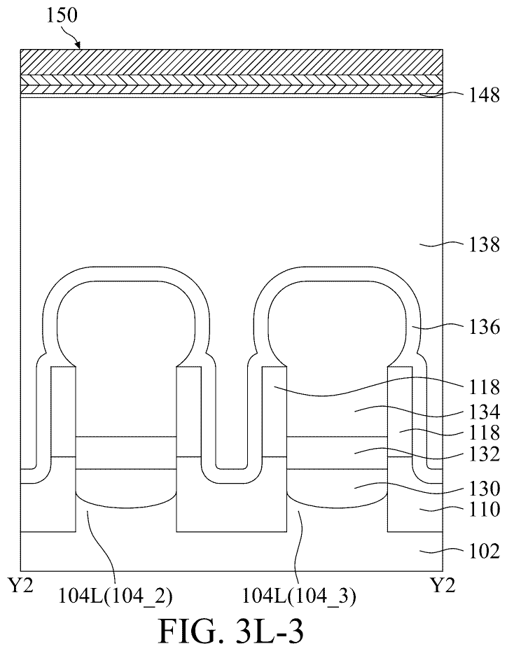

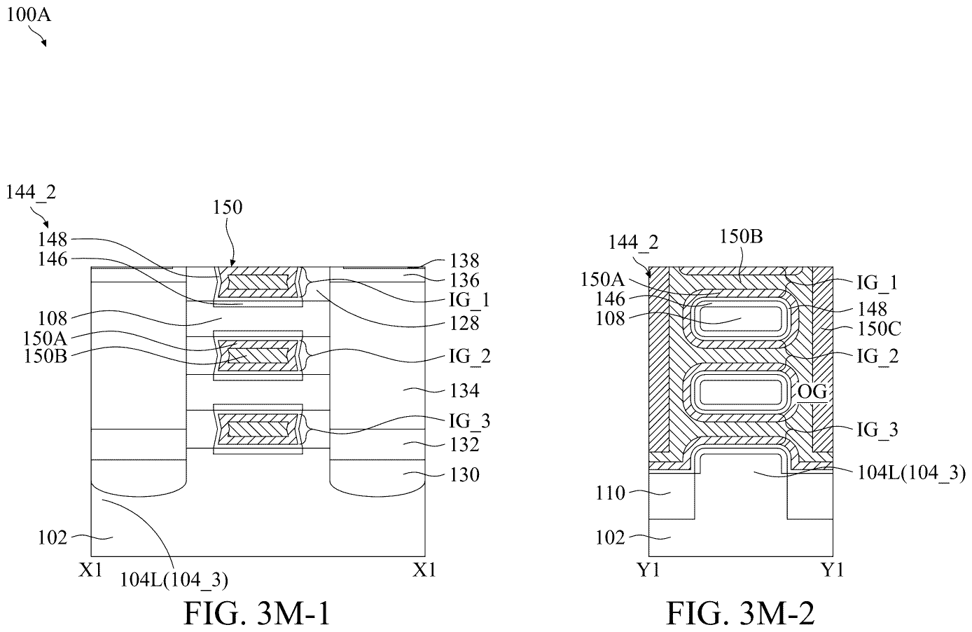

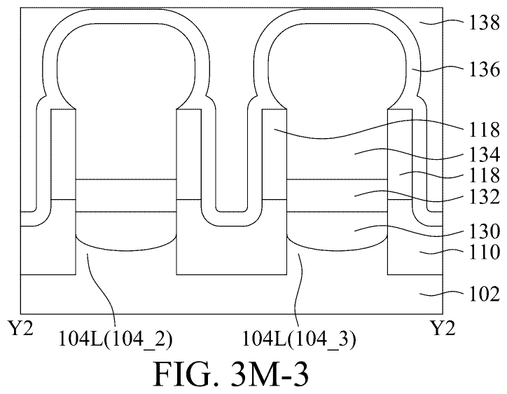

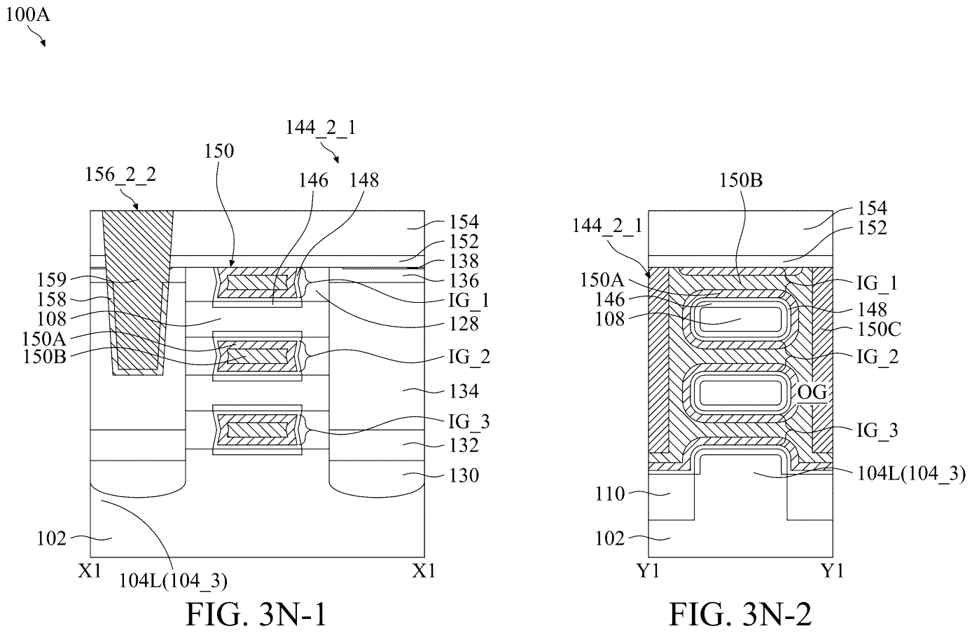

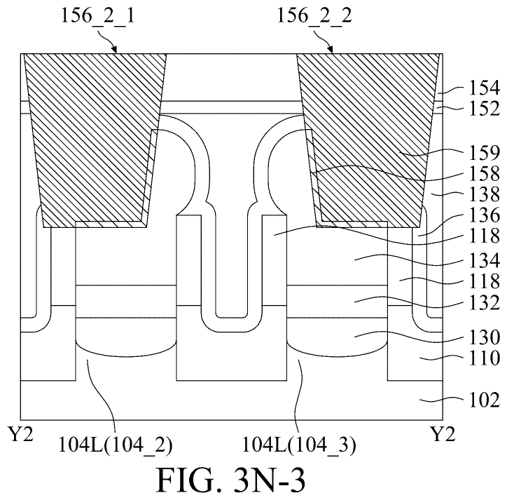

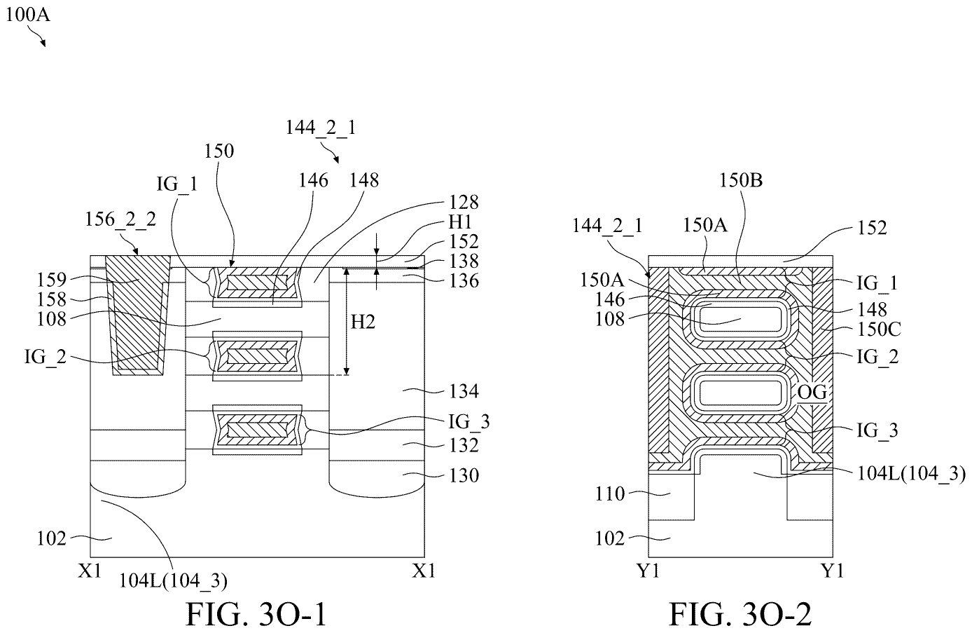

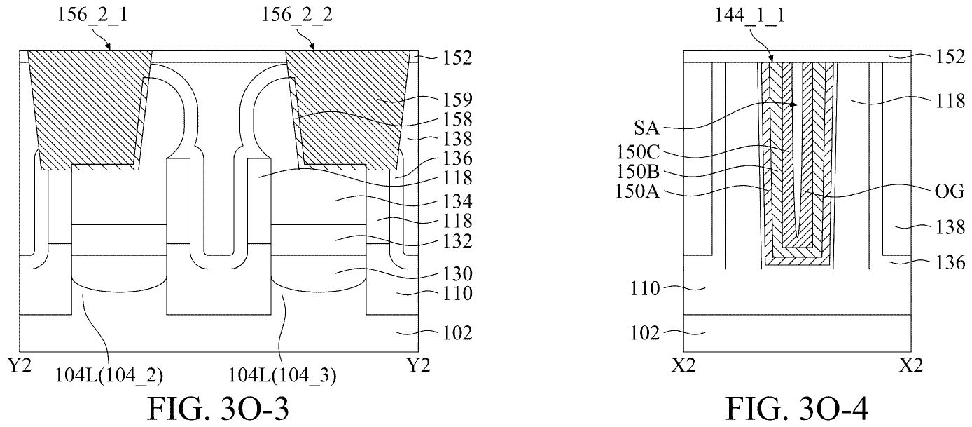

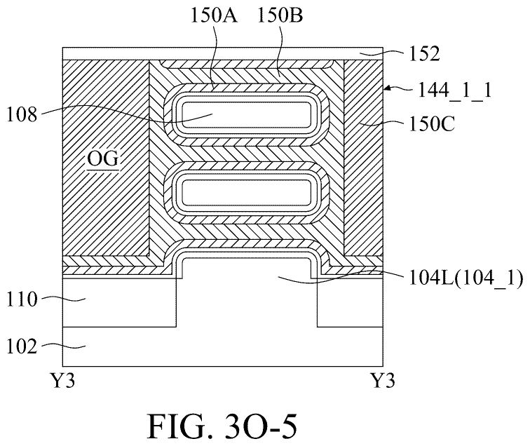

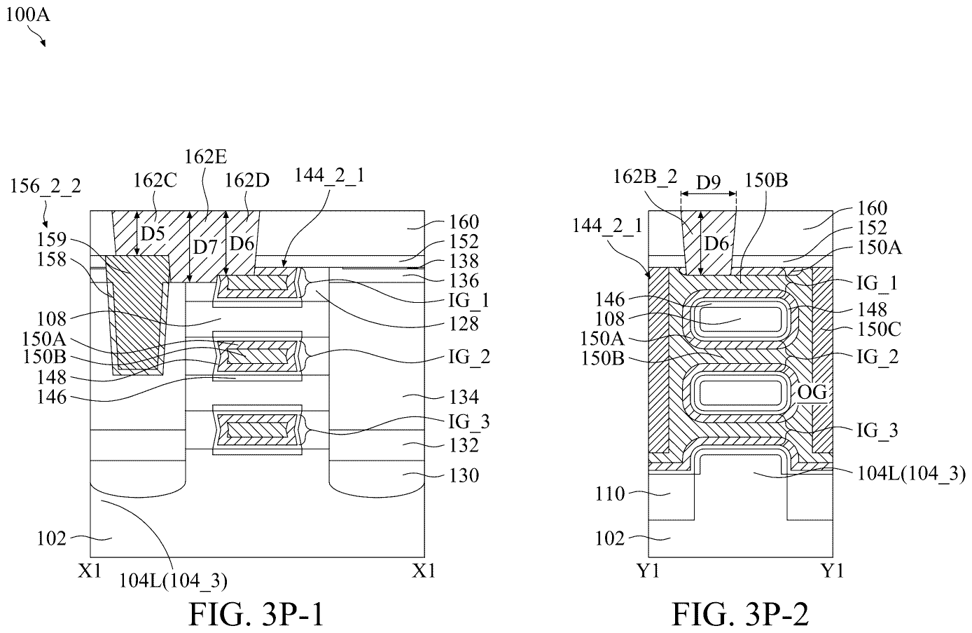

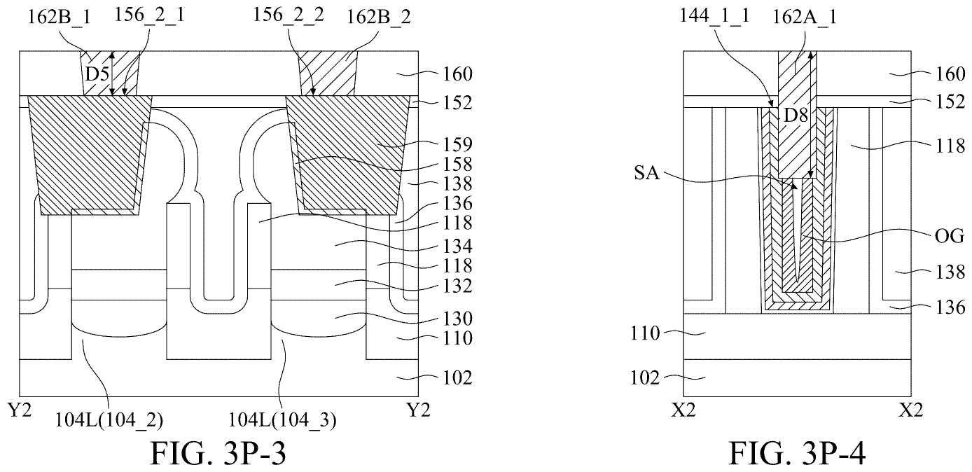

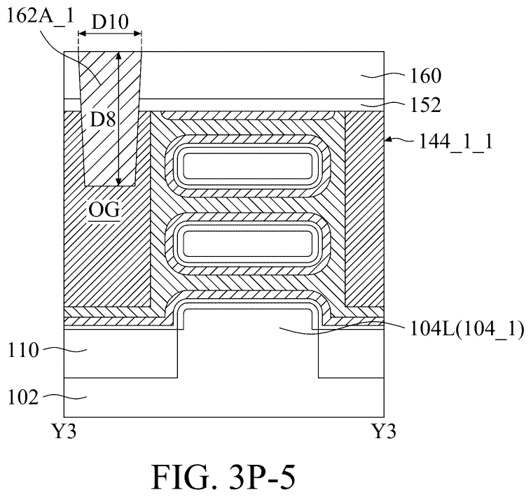

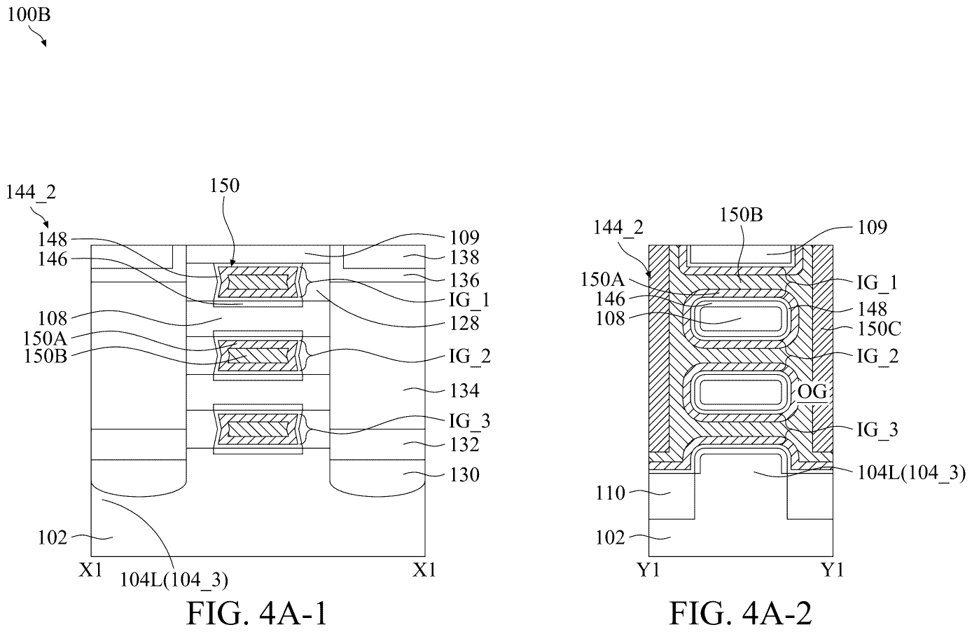

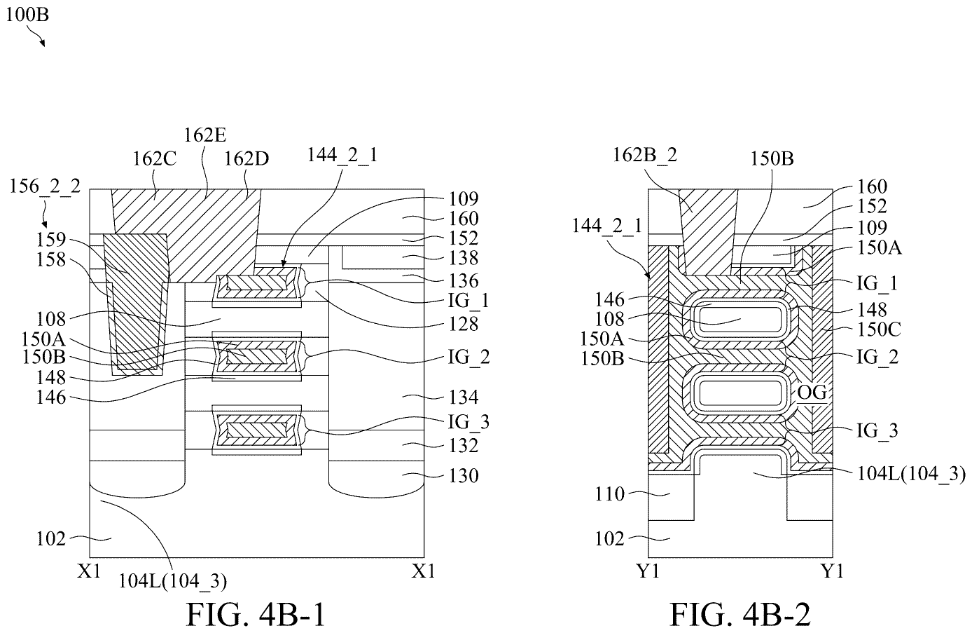

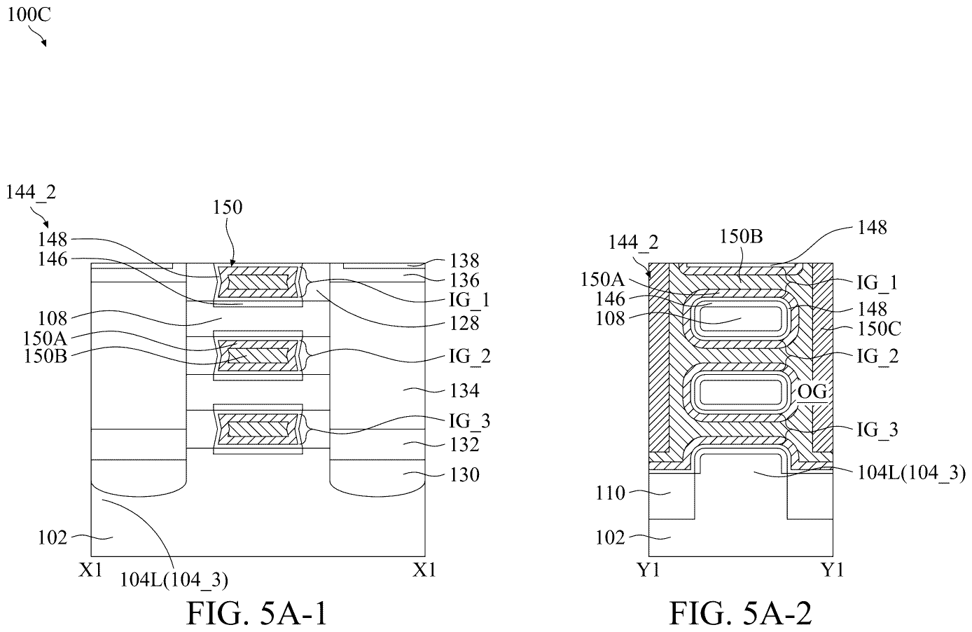

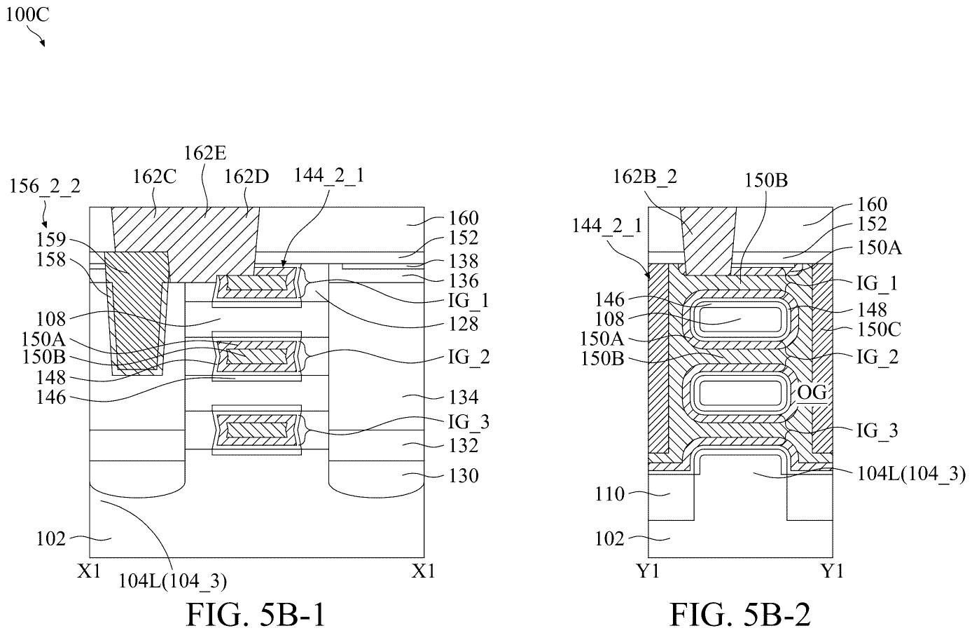

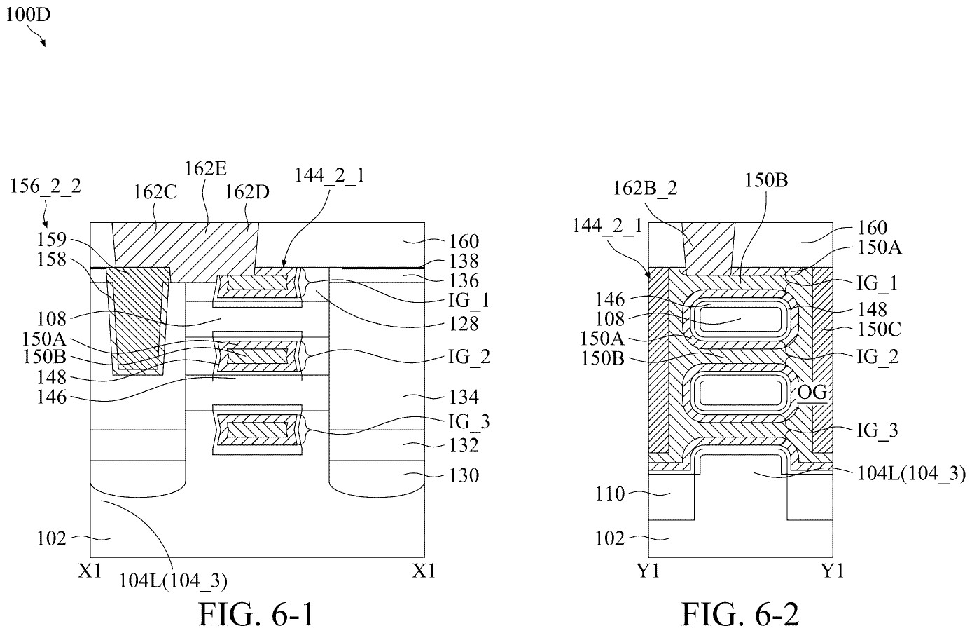

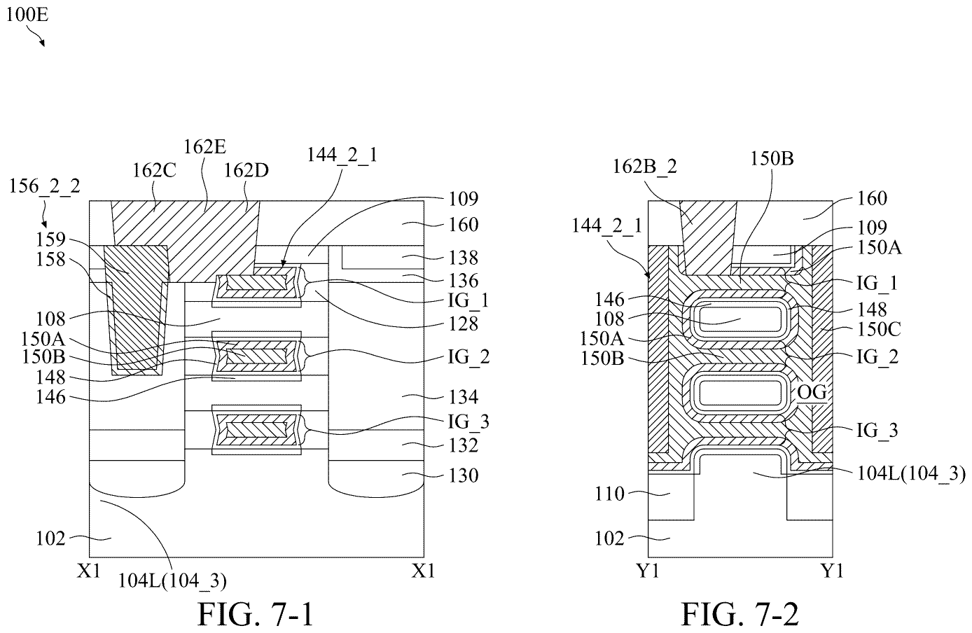

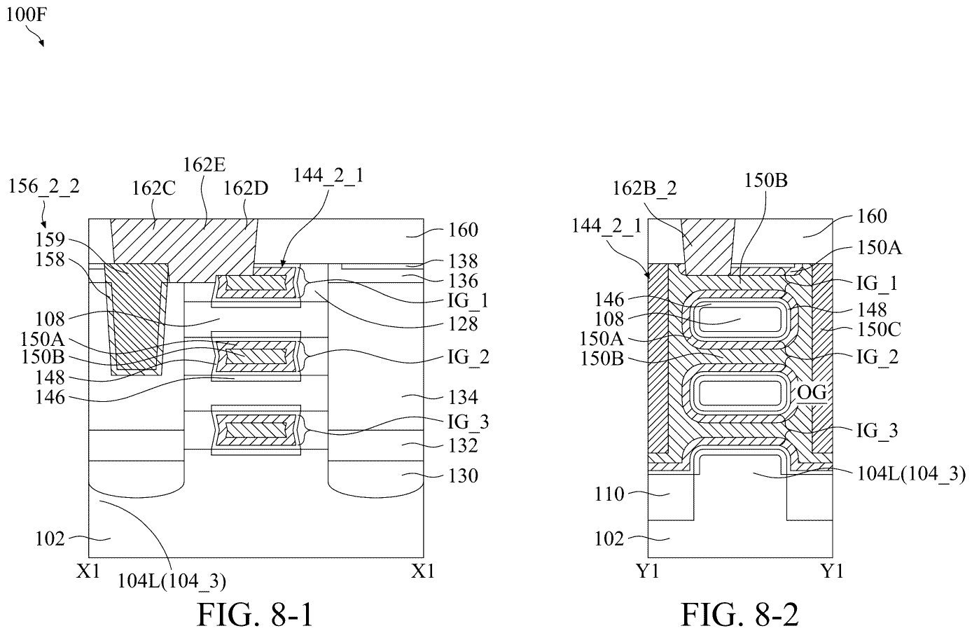

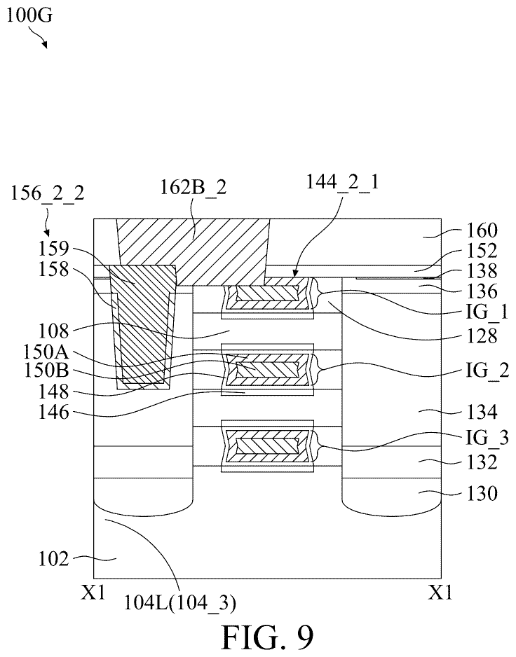

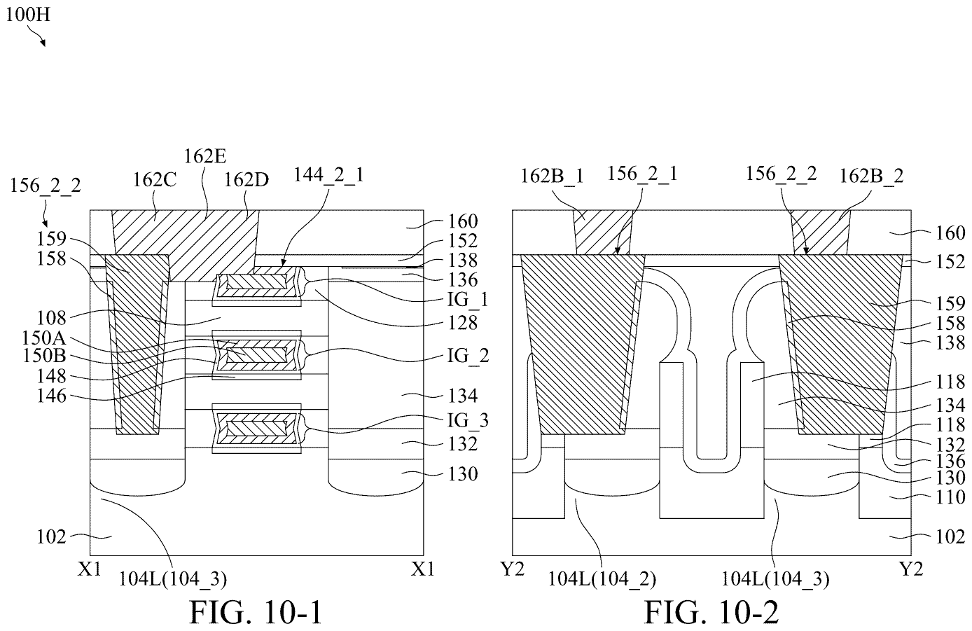

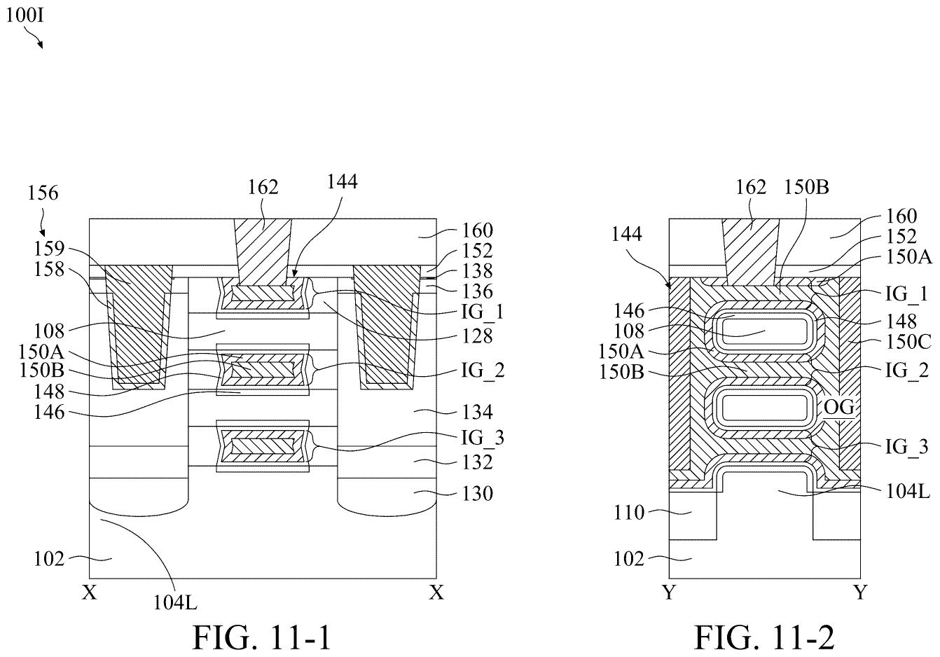

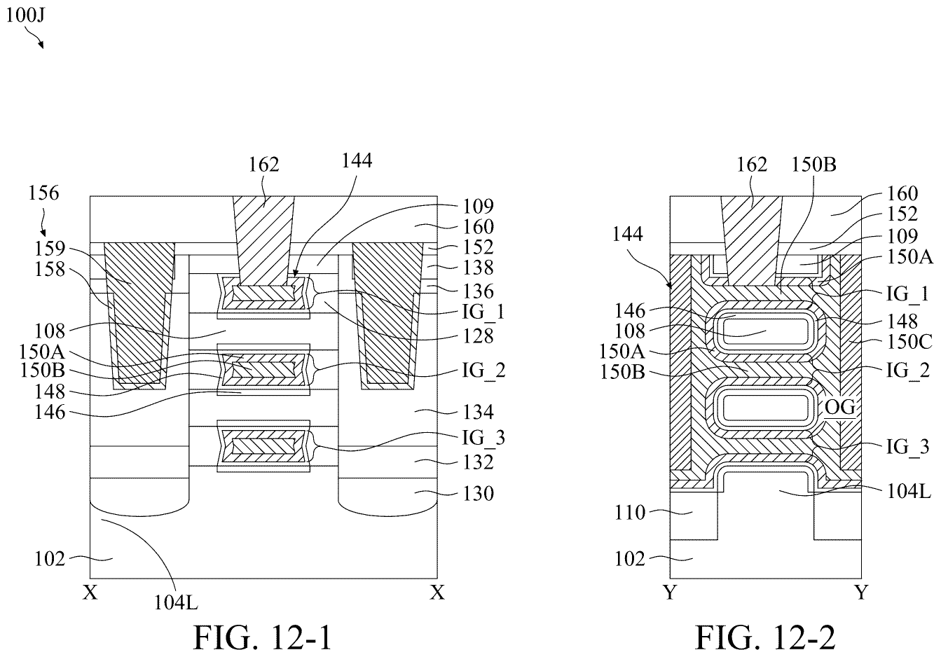

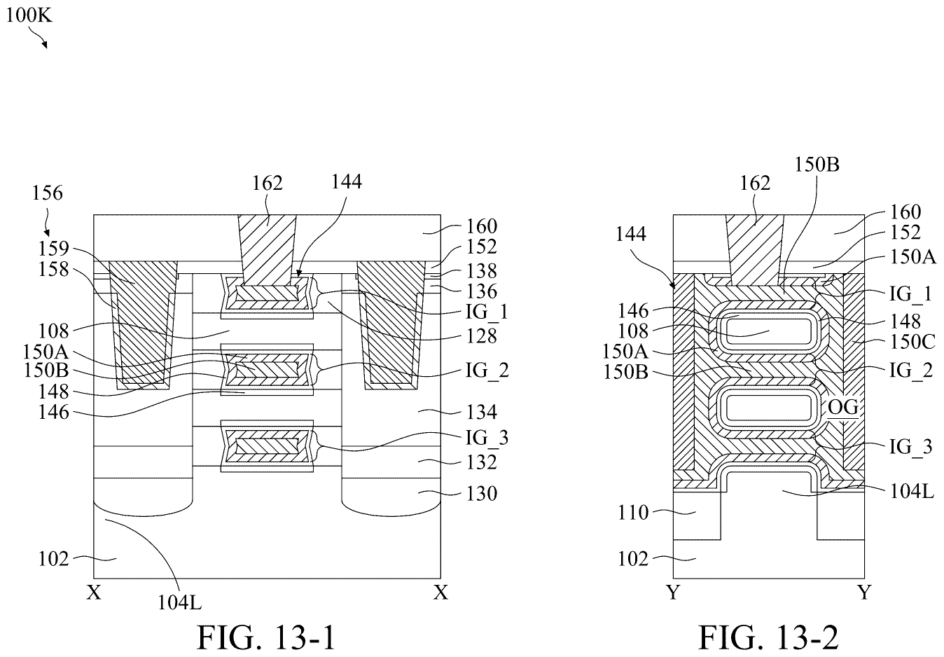

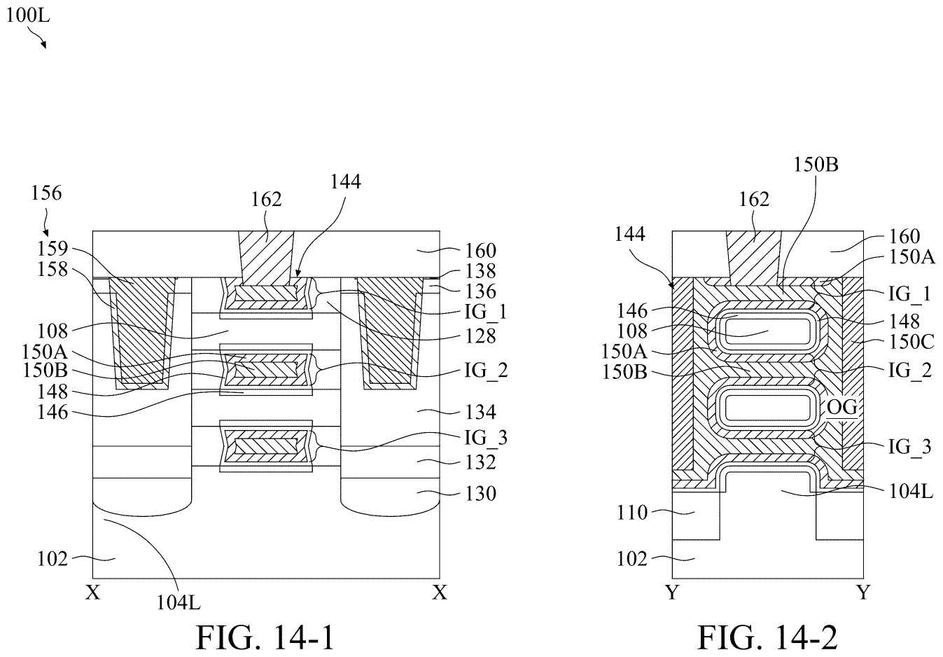

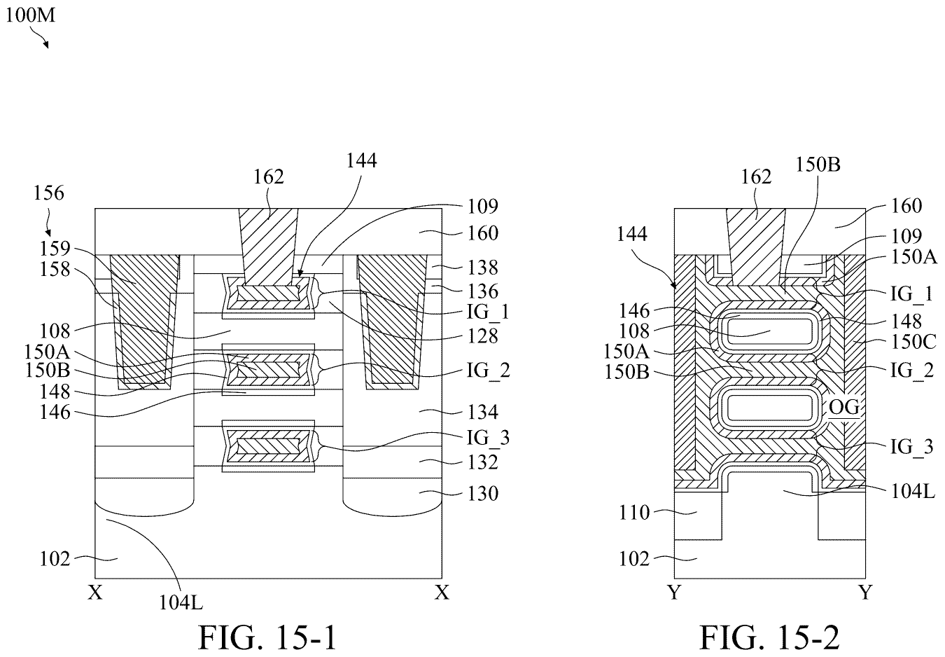

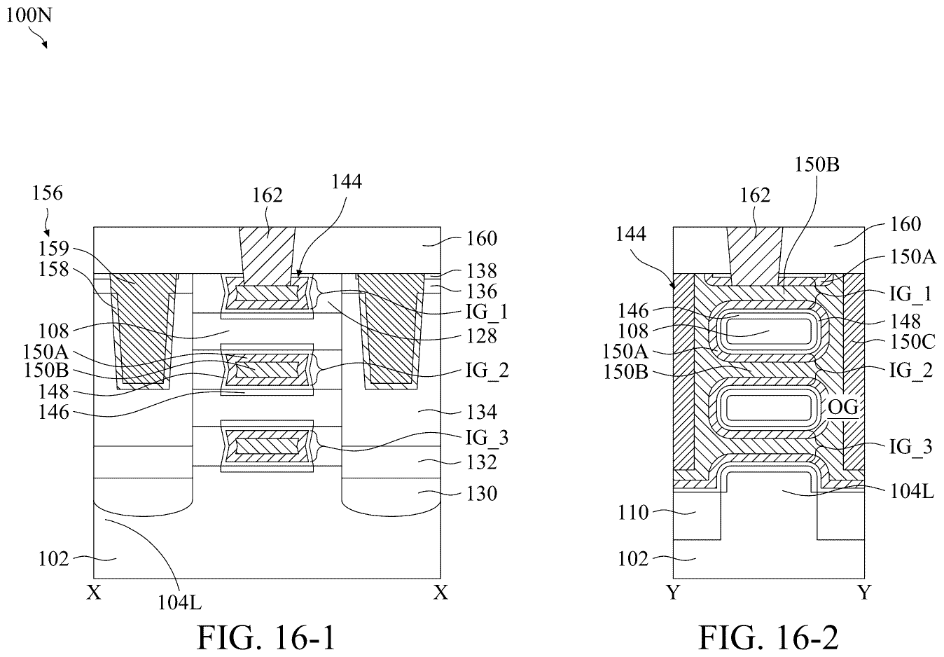

FIGS. 3A-1 through 3P-5 are cross-sectional views illustrating the formation of a semiconductor structure at various intermediate stages. FIGS. 3A-1, 3B-1, 3C-1, 3D-1, 3E-1, 3F-1, 3G-1, 3H-1, 31-1, 3J-1, 3K-1, 3L-1, 3M-1, 3N-1, 3O-1 and 3P-1 correspond to cross-section X1-X1 shown in FIG. 2. FIGS. 3A-2, 3B-2, 3C-2, 3D-2, 3E-2, 3F-2, 3K-2, 3L-2, 3M-2, 3N-2, 3O-2 and 3P-2 correspond to cross-section Y1-Y1 shown in FIG. 2. FIGS. 3C-3, 3D-3, 31-2, 3J-2, 3L-3, 3M-3, 3N-3, 3O-3 and 3P-3 correspond to cross-section Y2-Y2 shown in FIG. 2. FIGS. 3O-4 and 3P-4 correspond to cross-section X2-X2 shown in FIG. 2. FIGS. 3O-5 and 3P-5 correspond to cross-section Y3-Y3 shown in FIG. 2

FIGS. 3A-1 and 3A-2 illustrate a semiconductor structure 100A after an epitaxial stack and a cap layer 109, in accordance with some embodiments. A substrate 102 is provided, as shown in FIGS. 3A-1 and 3A-2, in accordance with some embodiments. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GalnP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

An epitaxial stack is formed over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be replaced with dielectric interposers which will be removed to form gaps to accommodate gate materials, and the second semiconductor layers 108 will form nanostructures (e.g., nanowires or nanosheets) that laterally extend between source/drain features and serve as the channel layers for the resulting semiconductor devices (such as nanostructure transistors), in accordance with some embodiments. Although two second semiconductor layers 108 are shown in FIGS. 3A-1 and 3A-2, the number is not limited to two, and can be one or three, and is less than 10.

A cap layer 109 is formed on the epitaxial stack, as shown in FIGS. 3A-1 and 3A-2, in accordance with some embodiments. The cap layer 109 is made of dielectric material such as silicon nitride (SiN), silicon oxynitride (SiON), silicon oxide (SiO₂), silicon carbide (SiC), oxygen-doped silicon carbide (SiC:O), oxygen-doped silicon carbonitride (Si(O) CN), or a combination thereof. In some embodiments, the cap layer 109 are made of high-k dielectric material such as Al₂O₃, LaO, HfO₂, Ta₂O₅, TiO₂, ZrO₂, or Y₂O₃; another suitable metal oxide, or a combination thereof. In some embodiments, the cap layer 109 is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

In some embodiments, the thickness T1 of each of the first semiconductor layers 106 is in a range from about 3 nm to about 20 nm, such as about 4 nm to about 12 nm. In some embodiments, the thickness T2 of each of the second semiconductor layers 108 is in a range from about 3 nm to about 20 nm, such as about 4 nm to about 12 nm. The thickness T3 of the cap layer 109 is in a range from about 3 nm to about 6 nm. In some embodiments, the cap layer 109 is thinner than the first semiconductor layers 106 and the second semiconductor layers 108.

A patterned mask layer 107 is formed on the cap layer 109, in accordance with some embodiments. The patterned mask layer 107 may be a patterned hard mask layer and/or a patterned photoresist material, in accordance with some embodiments. For example, a mask layer is formed, a patterned photoresist material is formed on the mask layer using a photolithography process, and the mask layer is etched to form the patterned mask layer 107 using a photolithography process. The photolithography process may include forming a photoresist material, performing a pre-exposure baking process, performing an exposure process using a mask (or a reticle), performing a post-exposure baking process, and performing a developing process. The etching process may be an anisotropic etching process such as dry plasma etching, an isotropic etching process such as dry chemical etching, remote plasma etching or wet chemical etching, and/or a combination thereof. The patterned photoresist material may be removed in the etching process, or by an additional process (e.g., ashing, etching or wet stripping process).

FIGS. 3B-1 and 3B-2 illustrate a semiconductor structure 100A after the formation of active regions 104 and an isolation structure 110, in accordance with some embodiments. The cap layer 109, the epitaxial stack including semiconductor layers 106 and 108 and the underlying substrate 102 are etched using the patterned mask layer 107, thereby forming trenches and active regions 104 (e.g., 104_1 to 104_4 in FIG. 2) protruding from between trenches, as shown in FIGS. 3B-1 and 3B-2, in accordance with some embodiments. The substrate 102 protruding from between the trenches forms the lower fin elements 104L of the active region 104, and the remainder of the epitaxial stack and the cap layer 109 forms the upper fin elements of the active regions 104, in accordance with some embodiments. In some embodiments, the active regions 104 are longitudinally oriented along the X direction.

An isolation structure 110 is formed to surround the lower fin elements 104L, as shown in FIG. 3B-2, in accordance with some embodiments. The isolation structure 110 is configured to electrically isolate active regions 104 from one another, and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O) CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process (e.g., chemical mechanical polishing (CMP), etching back process, or a combination thereof) is performed on the insulating material, in accordance with some embodiments. The insulating material is then recessed by an etching process (such as dry plasma etching and/or wet chemical etching) until the upper fin elements of the active regions 104 are exposed, in accordance with some embodiments. In some embodiments, the isolation structure 110 includes an oxide portion and a nitride portion over the oxide portion, which may reduce the loss of the isolation structure 110 in subsequent DOI

FIGS. 3C-1, 3C-2 and 3C-2 illustrate a semiconductor structure 100A after the formation of dummy gate structures 112 and spacer layers 118, in accordance with some embodiments. Dummy gate structures 112 are formed across the active regions 104 and the isolation structure 110, as shown in FIGS. 3B-1 and 3B-2, in accordance with some embodiments. The dummy gate structures 112 are configured as sacrificial structures and will be replaced with the final gate stacks, in accordance with some embodiments. In some embodiments, the dummy gate structures 112 are longitudinally oriented along the Y direction. The dummy gate structures 112 surround the channel regions of the active regions 104, in accordance with some embodiments.

Each of the dummy gate structures 112 includes a dummy gate dielectric layer 114 and a dummy gate electrode layer 116 over the dummy gate dielectric layer, in accordance with some embodiments. In some embodiments, the dummy gate dielectric layer 114 is conformally formed along the upper fin elements of the active regions 104 using ALD, CVD, thermal oxidation, physical vapor deposition (PVD), another suitable technique, or a combination thereof. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, and/or HfAlO.

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structures 112 using photolithography and etching processes. In some embodiments, the portion of the dummy gate structure 112 along the top surface of the active region 104 may have a footing profile (e.g., upwards-tapered sidewalls) because of the characteristics of the etching process.

Spacer layers 118 are formed along the opposite sidewalls of the dummy gate structures 112 and the opposite sidewalls of the active regions 104, as shown in FIGS. 3C-1 and 3C-3, in accordance with some embodiments. In some embodiments, the spacer layers 118 are made of a dielectric material, such as silicon nitride (SiN), silicon oxynitride (SiON), silicon oxide (SiO₂), oxygen-doped silicon carbide (SiC:O), oxygen-doped silicon carbonitride (Si(O) CN), silicon carbide (SiC), or another suitable dielectric material. In some embodiments, the formation of the spacer layers 118 includes globally and conformally dielectric material over the semiconductor structure 100A using ALD, CVD (such as LPCVD, PECVD or HDP-CVD or a combination thereof, followed by an anisotropic etching process, in accordance with some embodiments.

The vertical portions of the spacer layers 118 that are left remaining on the opposite sides of the dummy gate structures 112 may be referred to as gate spacer, and the vertical portions of the spacer layers 118 left on the opposite sides of the active regions 104 may be referred to as fin spacer. The gate spacer layers are used to offset the subsequently formed source/drain features and separate the source/drain features from the gate structure, in accordance with some embodiments. The fin spacer layers are used to constrain the lateral growth of subsequently formed source/drain features, in accordance with some embodiments.

FIGS. 3D-1, 3D-2 and 3D-3 illustrate a semiconductor structure 100A after the formation of source/drain recesses 120, in accordance with some embodiments. An etching process is performed to recess the source/drain regions of the active regions 104, thereby forming source/drain recesses 120, as shown in FIGS. 3D-1 and 3D-3, in accordance with some embodiments. The source/drain recesses 120 extend in a distance into the lower fin elements 104L, in accordance with some embodiments.

The etching process may be an anisotropic etching process such as dry plasma etching, an isotropic etching process such as dry chemical etching, remote plasma etching or wet chemical etching, and/or a combination thereof. The spacer layers 118 and the dummy gate structures 112 may serve as etch masks such that the source/drain recesses 120 are formed self-aligned on opposite sides of the dummy gate structures 112, in accordance with some embodiments.

FIGS. 3E-1 to 3F-2 illustrate a replacement process of the first semiconductor layers 106, in accordance with some embodiments. The replacement process may also be referred to as a Disposable Oxide Interposer (DOI) process. An etching process is performed to remove the first semiconductor layers 106 of the active regions 104, thereby forming gaps 122, as shown in FIGS. 3E-1 and 3E-2, in accordance with some embodiments. The etching processes include an isotropic etching process such as dry chemical etching, remote plasma etching or wet chemical etching, or a combination thereof.

FIGS. 3F-1 and 3F-2 illustrate a semiconductor structure 100A after the formation of the dielectric interposers 124, in accordance with some embodiments. Dielectric interposers 124 are formed in the gaps 122, as shown in FIGS. 3F-1 and 3F-2, in accordance with some embodiments. The dielectric interposers 124 are made of silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O) CN). The dielectric interposers 124 are made of a different material than the cap layer 109, and have a different etching selectivity than the cap layer 109, in accordance with some embodiments. In an embodiment, the dielectric interposers 124 are made of SiO, and the cap layer 109 is made of SiN.

The formation of the dielectric interposers 124 includes depositing a dielectric material over the semiconductor structure 100A to overfill the gaps 122, and performing an etching process to etch away the dielectric material outside the gaps 122, in accordance with some embodiments. In some embodiments, the etching process includes an anisotropic etching process such as dry plasma etching, an isotropic etching process such as dry chemical etching, remote plasma etching or wet chemical etching, or a combination thereof. As a result, the first semiconductor layers 106 of the active regions 104 are replaced with the dielectric interposers 124, in accordance with some embodiments. In an embodiment where the dielectric interposers 124 are made of silicon oxide, and the dielectric interposers 124 may also be referred to as Disposable Oxide Interposer (DOI) features.

FIG. 3G illustrates a semiconductor structure 100A after the formation of notches 126, in accordance with some embodiments. The etching process for forming the dielectric interposers 124 further laterally recesses, from the source/drain recesses 120, the dielectric interposers 124 thereby forming notches 126, in accordance with some embodiments. The notches 126 are located directly under the gate spacer layers, in accordance with some embodiments. The notches 126 are formed between adjacent second semiconductor layers 108, between the lowermost second semiconductor layer 108 and the lower fin element 104L, and the topmost second semiconductor layer 108 and the cap layer 109, in accordance with some embodiments.

FIG. 3H illustrates a semiconductor structure 100A after the formation of inner spacer layers 128, in accordance with some embodiments. Inner spacer layers 128 are formed in the notches 126, as shown in FIG. 3H, in accordance with some embodiments. The inner spacer layers 128 abut the recessed side surfaces of the dielectric interposer 128, in accordance with some embodiments. The inner spacer layers 128 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 128 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O) CN), and/or a combination thereof. In some embodiments, the inner spacer layers 128 are formed by depositing a dielectric material to fill the notches 126 using ALD, CVD (such as PECVD, LPCVD or HARP), another suitable technique, or a combination thereof, and the dielectric material outside the notches are then etched away using an anisotropic etching process such as dry plasma etching, an isotropic etching process such as dry chemical etching, remote plasma etching or wet chemical etching, or a combination thereof.

FIGS. 31-1 and 31-2 illustrate a semiconductor structure 100 A after the formation of semiconductor isolation layers 130, dielectric isolation layers 132, and source/drain features 134, in accordance with some embodiments. Semiconductor isolation layers 130 are grown on the lower fin elements 104L, as shown in FIGS. 31-1 and 31-2, in accordance with some embodiments. In some embodiments, the semiconductor isolation layers 130 are made of an epitaxial semiconductor material such as silicon, silicon germanium or germanium, formed by MBE, MOCVD, or VPE, another suitable technique, or a combination thereof. In an embodiment, the semiconductor isolation layers 130 are made of non-doped silicon.

Dielectric isolation layers 132 are optionally formed on the semiconductor isolation layers 130, as shown in FIGS. 31-1 and 31-2, in accordance with some embodiments. In some embodiments, the dielectric isolation layers 132 are made of dielectric material silicon oxide (SiO₂), silicon nitride (SiN), silicon carbide (SIC), silicon oxynitride (SiON), silicon carbon nitride (SiCN), silicon oxycarbonitride (SiOCN), and/or oxygen-doped silicon carbonitride (Si(O) CN). In some embodiments, the dielectric isolation layers 132 are formed a deposition followed by and etching-back processes.

In some embodiments, the sidewalls of the bottommost second semiconductor layers 108 are uncovered by the dielectric isolation layers 132. The semiconductor isolation layers 130 and the dielectric isolation layers 132 may be configured to reduce the total cell capacitance, in accordance with some embodiments.

Source/drain features 134 are grown from the exposed side surfaces of the second semiconductor layers 108 to fill the source/drain recesses 120 using an epitaxial growth process, as shown in FIGS. 31-1 and 31-2, in accordance with some embodiments. The epitaxial growth process may be MBE, MOCVD, or VPE, or another suitable technique. In some embodiments, the source/drain features 134 are formed on the dielectric isolation layers 132. In some embodiments, the top surface of the source/drain features 134 is lower than the bottom surface of the cap layer 109.

In some embodiments, the source/drain features 134 are made of any suitable semiconductor material for n-type semiconductor devices (e.g., n-channel nanostructure transistors) or p-type semiconductor devices (e.g., p-channel nanostructure transistors). In some embodiments, the source/drain features 134 are doped. The concentration of the dopant in the source/drain features 134 in a range from about 1×10¹⁹ cm⁻³ to about 6×10²¹ cm-3.

In some embodiments where the source/drain features 134 are formed in the p-type well, the source/drain features 134 are doped with the n-type dopant during the epitaxial growth process. For example, the n-type dopant may be phosphorous (P) or arsenic (As). The n-type source/drain features 134 are made of semiconductor material such as SiP, SiAs, SiCP, SiC, Si, GaAs, another suitable semiconductor material, or a combination thereof. For example, the n-type source/drain features 134 may be the epitaxially grown Si doped with phosphorous to form silicon:phosphor (Si:P) source/drain features and/or arsenic to form silicon:arsenic (Si:As) source/drain feature.

In some embodiments where the source/drain features 134 are formed in the n-type well, the source/drain features 134 are doped with the p-type dopant during the epitaxial growth process. For example, the p-type dopant may be boron (B) or BF₂. The p-type source/drain features 134 are made of semiconductor material such as SiGe, Si, GaAs, another suitable semiconductor material, or a combination thereof. In some embodiments, the p-type source/drain features 134 may be the epitaxially grown SiGe doped with boron (B) to form silicon germanium:boron (SiGe:B) source/drain feature.

FIGS. 3J-1 and 3J-2 illustrate a semiconductor structure 100A after the formation of a contact etching stop layer 136 and a first interlayer dielectric layer 138, in accordance with some embodiments. A contact etching stop layer 136 is formed over the semiconductor structure 100A to cover the source/drain features 134, as shown in FIGS. 3J-1 and 3J-2, in accordance with some embodiments. In some embodiments, the contact etching stop layer 136 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O) CN), silicon carbide (SiC), or another suitable dielectric material. In some embodiments, the contact etching stop layer 136 is globally and conformally deposited using ALD, CVD (such as LPCVD, PECVD, HDP-CVD and HARP), another suitable method, and/or a combination thereof.

A first interlayer dielectric layer 138 is formed over the contact etching stop layer 138, as shown in FIGS. 3J-1 and 3J-2, in accordance with some embodiments. The first interlayer dielectric layer 138 overfills the space between dummy gate structures 112, in accordance with some embodiments. In some embodiments, the first interlayer dielectric layer 138 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the dielectric material for the first interlayer dielectric layer 138 is deposited using such as CVD (such as HDP-CVD, PECVD, HARP or FCVD), another suitable technique, or a combination thereof. The dielectric materials for the contact etching stop layer 136 and the first interlayer dielectric layer 138 above the top surface of the dummy gate electrode layer 116 are removed using such as CMP, in accordance with some embodiments.

FIGS. 3K-1 and 3K-2 illustrate a semiconductor structure 100A after the formation of gate trenches 140 and gaps 142, in accordance with some embodiments. The dummy gate structures 112 are removed using one or more etching processes (e.g., an anisotropic etching process such as dry plasma etching, an isotropic etching process such as dry chemical etching, remote plasma etching or wet chemical etching, and/or a combination thereof) to form gate trenches 140 between the spacer layers 118, as shown in FIGS. 3K-1 and 3K-2, in accordance with some embodiments. In some embodiments, the gate trenches 140 expose the channel regions of the active regions 104. In some embodiments, the gate trenches 140 also expose the sidewalls of the spacer layers 118 facing the channel regions.

Afterward, an etching process is performed to remove the dielectric interposers 124 of the active regions 104 to form gaps 142, as shown in FIGS. 3K-1 and 3K-2, in accordance with some embodiments. The etching process may be an anisotropic etching process such as dry plasma etching, an isotropic etching process such as dry chemical etching, remote plasma etching or wet chemical etching, and/or a combination thereof. The inner spacer layers 128 may be used as an etching stop layer in the etching process, which may protect the source/drain features 134 from being damaged. In some embodiments, the gaps 142 also expose the sidewalls of the inner spacer layers 128 facing the channel regions.

The etching selectivity (e.g., greater than 10000) between the dielectric interposers 124 (e.g., SiO) and the second semiconductor layers 108 (e.g., Si) is much greater than the etching selectivity (e.g., about 170) between the first semiconductor layers 106 (e.g., SiGe) and the second semiconductor layers 108 (e.g., Si), in accordance with some embodiments. Therefore, the DOI process may reduce the loss of the second semiconductor layers 108 in the channel-releasing process.

After the etching process, the four main surfaces (the top surface, the bottom surface, and two side surfaces) of the second semiconductor layers 108 and the cap layer 109 are exposed, in accordance with some embodiments. The second semiconductor layers 108 serve as nanostructures 108 that function as channels of the resulting semiconductor device (e.g., nanostructure transistors such as GAA FET), in accordance with some embodiments. In some embodiments, a trimming process may be performed on the nanostructures 108 to shape the profiles of the nanostructures 108, e.g., rounding the corners of the nanostructures 108.

In some embodiments, the width W1 (the dimension in the Y direction) of the nanostructures 108 is less than the width W2 (the dimension in the Y direction) of the cap layer 109, as shown in FIG. 3K-2. In some embodiments, the dimension D1 of the gap 142 in the Z direction is less than the dimension D2 of the gap 142 in the X direction. In some embodiments, the dimension D4 of the gate trench 140 in the X direction is less than the dimension D3 of the gate trench 140 in the Z direction. In some embodiments, the dimension D2 of the gap 142 is different from the dimension D4 of the gate trench 140.

FIGS. 3L-1, 3L-2 and 3L-3 illustrate a semiconductor structure 100A after the formation of an interfacial layer 146, a gate dielectric layer 148 and a metal gate electrode layer 150, in accordance with some embodiments. An interfacial layer 146 is formed on the exposed surfaces of the nanostructures 108 and the exposed surfaces of the lower fin elements 104L, as shown in FIGS. 3L-1 and 3L-2, in accordance with some embodiments. The interfacial layer 146 wraps around the nanostructures 108, in accordance with some embodiments.

In some embodiments, the interfacial layer 146 is made of a chemically formed silicon oxide. In some embodiments, the interfacial layer 146 is nitrogen-doped silicon oxide. In some embodiments, the interfacial layer 146 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 104L is oxidized to form the interfacial layer 146, in accordance with some embodiments.

A gate dielectric layer 148 is formed conformally along the interfacial layer 146 to wrap around the nanostructures 108, as shown in FIGS. 3L-1, 3L-2 and 3L-3, in accordance with some embodiments. The gate dielectric layer 148 is further formed along the four main surfaces of the cap layer 109, in accordance with some embodiments. The gate dielectric layer 148 is further formed along the top surface of the isolation structure 110 and the sidewalls of the spacer layers 118 and the inner spacer layers 128 facing the channel region, in accordance with some embodiments.

The gate dielectric layer 148 may be a high-k dielectric layer. In some embodiments, the high-k dielectric layer is dielectric material with a high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Si₃N₄, oxynitrides (SiON), a combination thereof, or another suitable material. The high-k dielectric layer may be deposited using ALD, PVD, CVD, and/or another suitable technique.

A metal gate electrode layer 150 is formed to fill the remainders of the gate trenches 140 and gaps 142, as shown in FIGS. 3L-1, 3L-2 and 3L-3, in accordance with some embodiments. In some embodiments, the metal gate electrode layer 150 is made of more than one conductive material(s), such as a metal, metal alloy, conductive metal oxide and/or metal nitride, another suitable conductive material, and/or a combination thereof. For example, the metal gate electrode layer 146 may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof.

The metal gate electrode layer 150 may be a multi-layer structure with various combinations of a diffusion barrier layer, work function layers with a selected work function to enhance the device performance (e.g., threshold voltage) for n-channel FETs (e.g., the pull-down transistors and the pass-gate in FIG. 2) or p-channel FETs (e.g., the pull-up transistors in FIG. 2), a capping layer to prevent oxidation of work function layers, a glue layer to adhere work function layers to the next layer, and a metal fill layer to reduce the total resistance of gate stacks, and/or another suitable layer.

In some embodiments, the metal gate electrode layer 150 includes a first metal material 150A, a second metal material 150B, and a third metal material 150C which are sequentially deposited. In an embodiment, the first metal material 150A is a diffusion barrier layer (e.g., TiN), the second metal material 150B is a work function layer (e.g., TiAlN), and the third metal material 150C is a metal fill layer (e.g., W). In an embodiment, the first metal material 150A is a p-type work function layer, the second metal material 150B is an n-type work function layer, and the third metal material 150C is a metal fill layer. The metal gate electrode layer 150 may be formed using ALD, PVD, CVD, e-beam evaporation, or another suitable technique.

The portions of the metal gate electrode layer 150 inside the active regions 104 (i.e., formed vertically between the neighboring nanostructures 108, between the bottommost nanostructure 108 and the lower fin element 104L and between the topmost nanostructure 108 and the cap layer 109) are defined as inner gate electrodes IG, in accordance with some embodiments. The portion of the metal gate electrode layer 150 outside the active regions 104 is defined as an outer gate electrode OG, in accordance with some embodiments. Each of the nanostructures 108 is sandwiched between adjacent two inner gate electrodes IG, in accordance with some embodiments.

In the deposition process for forming the metal gate electrode layer 150, the metal materials (e.g., 150A-C) for the metal gate electrode layer 150 start growing on the surfaces of the components of the semiconductor structure 100A (e.g., exposed surfaces of the spacer layers 118, the inner spacer layers 128, the nanostructures 108 and the cap layer 109). Portions of the metal materials grown on these surfaces gradually fill the gate trenches 140 and the gaps 142, and then merge to each other as the trenches 140 and the gaps 142 shrink.

For the inner gate electrodes IG, the metal material (e.g., 150B) is merged in the Z direction because the dimension D1 (FIG. 3K-1) of the gap 142 is less than the dimension D2 (FIG. 3K-1) of the gap 142. As a result, each of the inner gate electrodes IG has a symmetrical profile. In specific, each of the inner gate electrodes IG includes an upper portion and a lower portion that are symmetrically distributed along a symmetric plane C1 in the X-Y plane, in accordance with some embodiments.

For each of the inner gate electrodes IG, in the cross-sectional view, the first metal material 150A has a closed loop profile, and the second metal material 150B is located within the closed loop profile of the first metal material 150A, as shown in FIG. 3L-1, in accordance with some embodiments. In some embodiments where the inner gate electrode IG includes the third metal material 150C, the second metal material 150B may have a closed loop profile, and the third metal material 150C is located within the closed loop profile of second metal material 150B. In some embodiments, the inner gate electrodes IG are free of seams or voids therein.

On the contrary, for the outer gate electrode OG, the metal material (e.g., 150C) is merged in the X direction because the dimension D4 (FIG. 3K-1) of the gate trench 140 is less than the dimension D3 (FIG. 3K-1) of the gate trench 142. As a result, the outer gate electrode OG IG has a symmetrical profile. In specific, the outer gate electrode OG includes a left portion and a right portion that are symmetrically distributed along a symmetric plane C2 in the Y-Z plane. In some embodiments, the outer gate electrode OG has different symmetry of the metal materials (e.g., 150A-C) from the inner gate electrodes IG. In some embodiments, a seam or void (not shown) may be formed in the outer gate electrode OG at the location where the metal materials merge.

FIGS. 3M-1, 3M-2 and 3M-3 illustrate a semiconductor structure 100A after a planarization process, in accordance with some embodiments. A planarization process such as CMP is performed on the semiconductor structure 100A to remove the outer gate electrode OG and the gate dielectric layer 148, the contact etching stop layer 136, the first interlayer dielectric layer 138 and the spacer layer 118 above the cap layer 109 of the active regions 104, as shown in FIGS. 3M-1, 3M-2 and 3M-3, in accordance with some embodiments. The planarization process may be performed with end-point mode, and includes an over-polishing step after the signal of the end-point is detected. The cap layer 109 of the active regions 104 is configured as a polishing stop layer to provide the signal of the end-point when the cap layer 109 is being polished.

In the over-polishing step, the semiconductor structure 100A is further polished to remove the cap layer 109 of the active regions 104 and the underlying gate dielectric layer 148 until the topmost inner gate electrode IG_1 is exposed, as shown in FIGS. 3M-1, 3M-2 and 3M-3, in accordance with some embodiments. After the planarization process, the top surfaces of the topmost inner gate electrode IG_1, the contact etching stop layer 136 and the first interlayer dielectric layer 138 are substantially coplanar (leveled), in accordance with some embodiments.

In some other embodiments, the over-polishing step of the planarization process ends when the gate dielectric layer 148 on the topmost inner gate electrode IG_1 is exposed. In some other embodiments where the planarization process includes no over-polishing step, the planarization process is completed when the cap layer 109 is exposed.

The interfacial layer 146, the gate dielectric layer 148 and the metal gate electrode layer 150 combine to from final gate stacks 144 (e.g., 144_1 and 144_2 in FIG. 2), in accordance with some embodiments. The final gate stacks 144 are longitudinally oriented in the Y direction. The final gate stacks 144 wrap around the nanostructures 108 and extend across the lower fin elements 104L and the isolation structure 110, in accordance with some embodiments. The final gate stack 144 wrapped around the nanostructures 108 is combined with the neighboring source/drain features 134 to form nanostructure transistors, in accordance with some embodiments. The final gate stacks 144 may engage the channel region so that current can flow between the source/drain features 134 during operation.

Once the final gate stacks 144 are formed, gate-cut features (not shown) are formed through the final gate stacks 144 to divide the final gate stacks 150 into several segments (e.g., 144_1_1, 144_1 2, 144_2_1 and 144_2_2 in FIG. 2), in accordance with some embodiments. In some embodiments, the gate-cut features are made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof.

FIGS. 3N-1 through 3O-5 illustrate the formation of an etching stop layer 152, a second interlayer dielectric layer 154 and contact plugs 156, in accordance with some embodiments. An etching stop layer 152 and a second interlayer dielectric layer 154 are sequentially formed over the semiconductor structure 100A, as shown in FIGS. 3N-1, 3N-2 and 3N-3, in accordance with some embodiments. In some embodiments, the etching stop layer 152 is made of dielectric material, such as silicon nitride (SIN), silicon oxide (SiO₂), silicon oxynitride (SiOC), silicon carbide (SiC), oxygen-doped silicon carbide (SiC:O), oxygen-doped silicon carbonitride (Si(O) CN), or a combination thereof. In some embodiments, the second interlayer dielectric layer 154 is made of dielectric material, such as USG, BPSG, FSG, PSG, BSG, and/or another suitable dielectric material. In some embodiments, the etching stop layer 152 and the second interlayer dielectric layer 154 are deposited using CVD (such as HDP-CVD, PECVD, HARP or FCVD), another suitable technique, or a combination thereof.

The contact plugs 156 are formed through the second interlayer dielectric layer 154, the etching stop layer 152, the first interlayer dielectric layer 138 and the contact etching stop layer 136, as shown in FIGS. 3N-1 and 3N-3, in accordance with some embodiments. The contact plugs 156 land on the source/drain features 134, in accordance with some embodiments. In some embodiments, the formation of the contact plugs 156 includes patterning the semiconductor structure 100A to form contact openings using photolithography and etching processes to expose the source/drain features 134. The contact openings extend a distance into the source/drain features 134. The etch process may include dry etching such as RIE, NBE, ICP etch, CCP etch, another suitable method, or a combination thereof.

Silicide layers 158 are formed on the exposed surfaces of the source/drain features 134, in accordance with some embodiments. In some embodiments, the silicide layers 158 are made of WSi, NiSi, TiSi and/or CoSi. In some embodiments, the formation of the silicide layers 158 includes depositing a metal material followed by one or more annealing processes. The semiconductive material (e.g., Si) from the source/drain features 134 react with the metal material to form the silicide layers 158, in accordance with some embodiments. Unreacted metal material is then removed, e.g., using wet etching.

Contact liners (not shown) are formed along the sidewalls of the contact openings using a deposition process and an etching back process, in accordance with some embodiments. In some embodiments, the contact liners are made of an insulating material such as a dielectric material (e.g., SiC, LaO, AlO, AION, ZrO, HfO, SiN, ZnO, ZrN, ZrAlO, TiO, TaO, YO, TaCN, ZrSi, SiOCN, SiOC, SiCN, SIN, HfSi, or SiO); or undoped silicon (Si).

Afterward, a metal bulk layer 159 is deposited to overfill the contact openings, in accordance with some embodiments. In some embodiments, one or more conductive materials are deposited using CVD, PVD, e-beam evaporation, ALD, ECP, ELD, another suitable method, or a combination thereof to overfill the contact openings. In some embodiments, the metal bulk layer 159 is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof. The one or more conductive materials over the second interlayer dielectric layer 154 are planarized using, for example, CMP.

In some embodiments, a barrier/adhesive layer (not shown) may optionally be deposited along the sidewalls and the bottom surfaces of the contact openings before the metal bulk layer 159 is deposited. The barrier/adhesive layer may be made of tantalum (Ta), tantalum nitride (TaN), titanium (Ti), titanium nitride (TiN), cobalt tungsten (CoW), another suitable material, or a combination thereof.

In some embodiments, the bottom surface of the contact plugs 156 is located at a position lower than the bottom surface of the topmost nanostructure 108. In some embodiments, the bottom surface of the contact plugs 156 may be lowered to a position that is substantially level with the bottom surface of the inner spacer layer 128 that is alongside the inner gate electrode IG_2. The extension of the contact plugs 156 into the source/drain features 134 may reduce the sheet resistance of the source/drain features 134, and may not increase the parasitic capacitance between the contact plugs 156 and the gate stack 144. In some other embodiments, the contact plugs 156 may extend to the dielectric isolation layers 132.

The planarization process for forming the contact plugs 156 is continuously performed on the semiconductor structure 100A until the etching stop layer 152 is exposed, as shown in FIGS. 3O-1 through 3O-5, in accordance with some embodiments. After the planarization process, the top surfaces of the contact plugs 156 and the top surfaces of the etching stop layer 152 are substantially coplanar (leveled), in accordance with some embodiments. FIG. 3O-4 illustrates that the portion of the outer gate electrode OG of the final gate stack 144_1_1 above the isolation structure 110 has a seam SA therein.

The contact plug 156 has a dimension H1 measured in the Z direction from the top surface of the topmost inner gate electrode IG_1 to the top surface of the contact plug 156. The dimension H1 may also be referred to MDH (metal diffusion height). In some embodiments, the dimension H1 is less than 8 nm, e.g., less than 5 nm. In some embodiments, the dimension H1 is less than the dimension of the inner gate electrode IG in the Z direction, the dimension of the inner spacer layer 128 in the Z direction, and the thickness of the nanostructure 108 in the Z direction.

The contact plug 156 has a dimension H2 measured in the Z direction from the top surface of the topmost inner gate electrode IG_1 to the bottom surface of the contact plug 156. The dimension H2 is greater than the dimension H1, and in a range from about 5 nm to about less than 40 nm. In some embodiments, the dimension H2 is greater than the dimension of the inner gate electrode IG in the Z direction, the dimension of the inner spacer layer 128 in the Z direction, and the thickness of the nanostructure 108 in the Z direction. In some embodiments, the dimension H2 is greater than the sum of the dimension of the inner gate electrode IG in the Z direction and the thickness of the nanostructure 108 in the Z direction.

FIGS. 3P-1, 3P-2, 3P-3, 3P-4 and 3P-5 illustrate a semiconductor structure 100A after the formation of a third interlayer dielectric layer 160 and vias 162A and 162B, in accordance with some embodiments. A third interlayer dielectric layer 160 is formed over the semiconductor structure 100A, as shown in FIGS. 3P-1 through 3P-5, in accordance with some embodiments. In some embodiments, the third interlayer dielectric layer 160 is made of dielectric material, such as USG, BPSG, FSG, PSG, BSG, and/or another suitable dielectric material. In some embodiments third interlayer dielectric layer 160 is deposited using CVD (such as HDP-CVD, PECVD, HARP or FCVD), another suitable technique, or a combination thereof.

Vias 162A are formed in and/or through the third interlayer dielectric layer 160 and the etching stop layer 152 and land on the outer gate electrode OG, as shown in FIGS. 3P-4 and 3P-5, in accordance with some embodiments. In some embodiments, the via 162A 1 extends a distance into the final gate stack 144_1_1. Vias 162B are formed in and/or through the third interlayer dielectric layer 160 and the etching stop layer 152 and land on both the contact plugs 156 and the topmost inner gate electrode IG_1, as shown in FIGS. 3P-1, 3P-2 and 3P-3, in accordance with some embodiments. In some embodiments, the via 162B_2 extends a distance into the final gate stack 144_2_1 and the topmost inner spacer layer 128.

In some embodiments, the formation of the vias 162A and vias 162B includes patterning the semiconductor structure 100A using a patterning process including photolithography and etching processes to form via openings (where the vias 162A and vias 162B are to be formed) exposing the final gate stacks 144 and contact plugs 156. The etch processes may include dry etching such as RIE, NBE, ICP etch, CCP etch, another suitable method, or a combination thereof. The patterning process for the vias 162A and the patterning process for the vias 162B are performed separately, in accordance with some embodiments.

Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the third interlayer dielectric layer 160 are planarized using, for example, CMP. After the planarization process, the top surfaces of the vias 162A and 162B and the top surface of the third interlayer dielectric layer 160 are substantially coplanar, in accordance with some embodiments.

The vias 162A and vias 162B may have a multilayer structure, for example, including a barrier/adhesive layer (e.g., tantalum (Ta), tantalum nitride (TaN), titanium (Ti), titanium nitride (TiN), cobalt tungsten (CoW), another suitable material, or a combination thereof) and a metal bulk layer (e.g., cobalt (Co), nickel (Ni), tungsten (W), titanium (Ti), tantalum (Ta), copper (Cu), aluminum (Al), ruthenium (Ru), molybdenum (Mo), another suitable metal material, or a combination thereof).

In some embodiments, the vias 162B includes a first portion 162C directly on the contact plug 156, a second portion 162D directly on the gate stack 144 and a third portion 162E directly on the inner spacer layer 128, as shown in FIG. 3P-1. In some embodiments, due to the difference in the etching selectivity between the contact plugs 156, the metal gate electrode layer 150 and the inner spacer layer 128, the bottom surface of the first portion 162C is higher than the bottom surface of the second portion 162B, and the bottom surface of the second portion 162B is higher than the bottom surface of the third portion 162C. The dimension D5 of the first portion 162C in the Z direction is less than the dimension D6 of the second portion 162D in the Z direction, and the dimension D6 is less than the dimension D7 of the third portion 162E in the Z direction. In some embodiments, the via 162B is in direct contact with the source/drain feature 134, as shown in FIG. 3P-1.

In some embodiments, the bottom surface of the vias 162A is lower than the bottom surface of the vias 162B. In some embodiments, because the vias 162A is disposed corresponding (overlapping) to the isolation structure 110 on the outer gate electrode OG, the vias 162A may extend into the gate stack 144 into a deeper position than the second portion 162D of the vias 162B without damaging nanostructures 108, thereby reducing the contact resistance of the vias 162A.

In some embodiments, the dimension D8 of the vias 162A in the Z direction is greater than the dimensions D5, D6 and D7 of the vias 162B. In some embodiments, the dimension D9 of the vias 162B in the X direction is different than the dimension D10 of the vias 162A. FIG. 3P-4 illustrates that the via 162A_1 is disposed directly on the seam SA within the outer gate electrode OG.

In accordance with the embodiments of the present disclosure, the inner gate electrodes IG has substantially the same configuration and symmetry of the metal materials (e.g., 150A-C) as each other and substantially the same critical dimension (e.g., substantially equal to the dimension D2 in FIG. 3K-1). Therefore, the nanostructures sandwiched between inner gate electrodes IG may have consistent threshold voltage with each other, which may improve the performance, stability, and reliability of the resulting semiconductor device.

In addition, due to the formation of the cap layer 109, the planarization process for polishing the final gate stack 144 may be precisely controlled, and thus the height of the portion (i.e., topmost inner gate electrode IG_1) of the gate electrode layer 150 above the topmost nanostructure 108 may also be precisely controlled. If the portion of the gate electrode layer 150 above the topmost nanostructure is too high, the parasitic capacitance may be high. If the portion of the gate electrode layer 150 above the topmost nanostructure is too low, the risk of damaging the topmost nanostructure may increase. Therefore, the formation of the cap layer 109 may help enhance the performance (e.g., speed) of the resulting semiconductor device.

In addition, the reduction of the dimension H1 of the contact plug 156 may reduce the fringe parasitic capacitance, which may further enhance the performance (e.g., speed) of the resulting semiconductor device.

In addition, the removal of the portion of the final gate stack 144 along the top surface of the active region 104 by the planarization process may reduce the risk of the extrusion of the final gate stack from the gate spacer layer toward the source/drain features 134 caused by the footing profile of the dummy gate structure. Therefore, the reliability of the resulting semiconductor device may be improved.

In addition, the etching stop layer 152 remains on the topmost inner gate electrode IG_1, which may reduce the oxidation of the metal gate electrode layer 150. Therefore, the risk of the vibration of the threshold voltage may be reduced.

It should be understood that the semiconductor structure 100A may undergo further CMOS processes to form various features over the semiconductor structure 100A, such as a multilayer interconnect structure (e.g., metal lines, inter metal dielectric layers, passivation layers, etc.). The embodiments of FIGS. 3A-1 through 3P-5 are discussed in the context of the nano-sheet transistors, the embodiments of the present disclosure may be applied to fork-sheet transistors, CFET (complementary FET), and the like.

FIGS. 4A-1 through 4B-2 are cross-sectional views illustrating the formation of a semiconductor structure 100B at various intermediate stages, in accordance with some embodiments of the disclosure. The embodiments of FIGS. 4A-1 through 4B-2 are similar to the embodiments of FIGS. 3A-1 to 3P-5 except that the planarization process is completed when the cap layer 109 is exposed.

Continuing from FIGS. 3L-1, 3L-2 and 3L-3, a planarization process such as CMP is performed to remove the outer gate electrode OG, the gate dielectric layer 148, the contact etching stop layer 136, the first interlayer dielectric layer 138 and the spacer layer 118 until the cap layer 109 of the active regions 104 is exposed, as shown in FIGS. 4A-1 and 4A-2, in accordance with some embodiments. After the planarization process, the top surfaces of the cap layer 109, the contact etching stop layer 136 and the first interlayer dielectric layer 138 are substantially coplanar (leveled), in accordance with some embodiments. The cap layer 109 remains on the topmost inner gate electrode IG_1, which may reduce the oxidation of the metal gate electrode layer 150. Therefore, the risk of the vibration of the threshold voltage may be reduced.

The steps described above in FIGS. 3N-1 through 3P-5 are performed, thereby forming the etching stop layer 138, the contact etching stop layer 156, the third interlayer dielectric layer 160 and the vias 162A and 162B, as shown in FIGS. 4B-1 and 4B-2, in accordance with some embodiments. In some embodiments, the vias 162B further penetrate through the cap layer 109 to land on the topmost inner gate electrode IG_1.

FIGS. 5A-1 through 5B-2 are cross-sectional views illustrating the formation of a semiconductor structure 100C at various intermediate stages, in accordance with some embodiments of the disclosure. The embodiments of FIGS. 5A-1 through 5B-2 are similar to the embodiments of FIGS. 3A-1 to 3P-5 except that the over-polishing step of the planarization process ends when the gate dielectric layer 148 on the topmost inner gate electrode IG_1 is exposed.

Continuing from FIGS. 3L-1, 3L-2 and 3L-3, a planarization process such as CMP is performed to remove the outer gate electrode OG, the gate dielectric layer 148, the contact etching stop layer 136, the first interlayer dielectric layer 138 and the spacer layer 118 above the cap layer 109 of the active regions 104, in accordance with some embodiments. In the over-polishing step, the semiconductor structure 100C is further polished to remove the cap layer 109 of the active regions 104 until the gate dielectric layer 148 on the topmost inner gate electrode IG_1 is exposed, as shown in FIGS. 5A-1 and 5A-2, in accordance with some embodiments. After the planarization process, the top surfaces of the gate dielectric layer 148, the contact etching stop layer 136 and the first interlayer dielectric layer 138 are substantially coplanar (leveled), in accordance with some embodiments. The gate dielectric layer 148 remains on the topmost inner gate electrode IG_1, which may reduce the oxidation of the metal gate electrode layer 150. Therefore, the risk of the vibration of the threshold voltage may be reduced.

The steps described above in FIGS. 3N-1 through 3P-5 are performed, thereby forming the etching stop layer 138, the contact etching stop layer 156, the third interlayer dielectric layer 160 and the vias 162A and 162B, as shown in FIGS. 5B-1 and 5B-2, in accordance with some embodiments. In some embodiments, the vias 162B further penetrate through the gate dielectric layer 148 to land on the topmost inner gate electrode IG 1.

FIGS. 6-1 and 6-2 are cross-sectional views of a semiconductor structure 100D, in accordance with some embodiments of the disclosure. The embodiments of FIGS. 6-1 through 6-2 are similar to the embodiments of FIGS. 3P-1 and 3P-2 except that the etching stop layer 152 is removed.

The planarization process for forming the contact plugs 156 are performed until the topmost inner gate electrode stack IG_1 is exposed, as shown in FIGS. 6-1 and 6-2, in accordance with some embodiments. After the planarization process, the top surfaces of the contact plugs 156 and the topmost inner gate electrode stack IG_1 are substantially coplanar (leveled), in accordance with some embodiments. As a result, the dimension H1 (FIG. 3O-1) of the contact plug 156 above the top surface of the topmost inner gate electrode IG 1 is about zero. Therefore, the performance (e.g., speed) of the resulting semiconductor device may be further enhanced.

FIGS. 7-1 and 7-2 are cross-sectional views of a semiconductor structure 100E, in accordance with some embodiments of the disclosure. The embodiments of FIGS. 7-1 and 7-2 are similar to the embodiments of FIGS. 4B-1 and 4B-2 except that the etching stop layer 152 is removed. After the planarization process for forming the contact plugs 156, the top surfaces of the contact plugs 156 and the cap layer 109 are substantially coplanar (leveled), in accordance with some embodiments.

FIGS. 8-1 and 8-2 are cross-sectional views of a semiconductor structure 100F, in accordance with some embodiments of the disclosure. The embodiments of FIGS. 8-1 and 8-2 are similar to the embodiments of FIGS. 5B-1 and 5B-2 except that the etching stop layer 152 is removed. After the planarization process for forming the contact plugs 156, the top surfaces of the contact plugs 156 and the gate dielectric layer 148 on the topmost inner gate electrode stack IG_1 are substantially coplanar (leveled), in accordance with some embodiments.

FIG. 9 is a cross-sectional view of a semiconductor structure 100G, in accordance with some embodiments of the disclosure. The embodiments of FIG. 9 are similar to the embodiments of FIG. 3P-1 except that the bottom surface of the second portion of the via 162B_2 directly on the gate stack 144 is substantially level with the bottom surface of the third portion of the via 162B_2 directly on the inner spacer layer 128.

FIGS. 10-1 and 10-2 are cross-sectional views of a semiconductor structure 100H, in accordance with some embodiments of the disclosure. The embodiments of FIGS. 10-1 and 10-2 are similar to the embodiments of FIGS. 3P-1 and 3P-3 except that the contact plug 156 extends into the dielectric isolation layers 132.

Although the embodiments of FIGS. 3A-1 through 10-2 are discussed in the context of SRAM cell region, the concept of the embodiments may be applied to other device regions such as a logic device region, an analog region, a peripheral region, and/or a combination thereof, in accordance with some embodiments. FIGS. 11-1 and 11-2 are cross-sectional views of a semiconductor structure 100I corresponding to line X-X and line Y-Y of FIG. 1, in accordance with some embodiments of the disclosure. The formation of the semiconductor structure 100I of FIGS. 11-1 and 11-2 are similar to the semiconductor structure 100A of FIGS. 3P-1 and 3P-2 except for a via 162.

The cap layer 109 of the active region 104 is removed in the planarization process for forming final gate stacks 144, as shown in FIGS. 11-1 and 11-2, in accordance with some embodiments. A via 162 is formed corresponding to (overlapping) the active region 104, in accordance with some embodiments. The via 162 does not land on contact plugs 156. The via 162 extends into the topmost inner gate electrode IG_1 of the final gate stack 144 and above the topmost nanostructure 108.

FIGS. 12-1 and 12-2 are cross-sectional views of a semiconductor structure 100J corresponding to line X-X and line Y-Y of FIG. 1, in accordance with some embodiments of the disclosure. The embodiments of FIGS. 12-1 and 12-2 are similar to the embodiments of FIGS. 11-1 and 11-2 except that the planarization process for forming the final gate stack 144 is completed when the cap layer 109 is exposed.

FIGS. 13-1 and 13-2 are cross-sectional views of a semiconductor structure 100K corresponding to line X-X and line Y-Y of FIG. 1, in accordance with some embodiments of the disclosure. The embodiments of FIGS. 13-1 and 13-2 are similar to the embodiments of FIGS. 11-1 and 11-2 except that the over-polishing step of the planarization process ends when the gate dielectric layer 148 on the topmost inner gate electrode IG_1 is exposed.

FIGS. 14-1 and 14-2 are cross-sectional views of a semiconductor structure 100L corresponding to line X-X and line Y-Y of FIG. 1, in accordance with some embodiments of the disclosure. The embodiments of FIGS. 14-1 and 14-2 are similar to the embodiments of FIGS. 11-1 and 11-2 except that the etching stop layer 152 is removed in the planarization process for forming the contact plugs 156. After the planarization process, the top surfaces of the contact plugs 156 and the topmost inner gate electrode stack IG_1 are substantially coplanar (leveled), in accordance with some embodiments.

FIGS. 15-1 and 15-2 are cross-sectional views of a semiconductor structure 100L corresponding to line X-X and line Y-Y of FIG. 1, in accordance with some embodiments of the disclosure. The embodiments of FIGS. 15-1 and 15-2 are similar to the embodiments of FIGS. 12-1 and 12-2 except that the etching stop layer 152 is removed. After the planarization process for forming the contact plugs 156, the top surfaces of the contact plugs 156 and the cap layer 109 are substantially coplanar (leveled), in accordance with some embodiments.

FIGS. 16-1 and 16-2 are cross-sectional views of a semiconductor structure 100M, in accordance with some embodiments of the disclosure. The embodiments of FIGS. 16-1 and 16-2 are similar to the embodiments of FIGS. 13B-1 and 13B-2 except that the etching stop layer 152 is removed. After the planarization process for forming the contact plugs 156, the top surfaces of the contact plugs 156 and the gate dielectric layer 148 on the topmost inner gate electrode stack IG_1 are substantially coplanar (leveled), in accordance with some embodiments.

As described above, the nanostructures 108 are sandwiched between the inner gate electrodes IG, each of which may have substantially the same configuration and symmetry of the metal materials (e.g., 150A-C). Therefore, the performance, stability, and reliability of the resulting semiconductor device may be improved. In addition, the contact plug 156 may be polished so that its top surface is level with the etching stop layer 152 or the topmost inner gate electrode IG_1, which may further enhance the performance (e.g., speed) of the resulting semiconductor device. Furthermore, the bottom of the contact plug 156 may lowered to a position that is substantially level with the bottom surface of the inner spacer layer 128 that is alongside the inner gate electrode IG 2. Therefore, the resistance of the source/drain features may be reduced without increasing the parasitic capacitance.

Embodiments of a semiconductor structure and the method for forming the same may be provided. The method for forming the semiconductor structure includes forming a gate electrode layer to wrap around a plurality of channel layers and a cap layer over the channel layers, and polishing the gate electrode layer at least until the cap layer is exposed. Because the channel layers are sandwiched between the inner gate electrodes, the performance, stability, and reliability of the resulting semiconductor device may be improved.

In some embodiments, a method for forming a semiconductor structure is provided. The method includes forming an active region including a plurality of channel layers and a cap layer above the plurality of channel layers, forming a source/drain feature adjoining the channel layers of the active region, forming a gate stack to wrap around the channel layers and the cap layer of the active region, polishing the gate stack at least until the cap layer of the active region is exposed, and forming a contact plug on the source/drain feature.

In some embodiments, a method for forming a semiconductor structure is provided. The method includes forming a stack of alternating first semiconductor layers and second semiconductor layers on the substrate. The method includes forming a dielectric layer on the stack. The method includes patterning the dielectric layer, the stack and the substrate into the active region. The method includes replacing the first semiconductor layers of the active region with dielectric interposers. The method includes removing the dielectric interposers. The method includes forming a gate electrode layer to surround the dielectric layer and the second semiconductor layers of the active region. The method includes removing the gate electrode layer and the dielectric layer of the active region.

In some embodiments, a semiconductor structure is provided. The semiconductor structure includes a plurality of nanostructures, a source/drain feature adjoining the nanostructures, a gate dielectric layer surrounding the nanostructures, and a gate electrode layer on the gate dielectric layer and extending in a first horizontal direction. The gate electrode layer is divided into a first inner gate electrode above the plurality of nanostructures and a second inner gate electrode between two adjacent nanostructures. The first inner gate electrode includes a first metal material and a second metal material. In a cross-sectional view, the first metal material surrounds four sides of the second metal material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming an active region including a plurality of channel layers and a cap layer above the plurality of channel layers;
forming a source/drain feature adjoining the channel layers of the active region;
forming a gate stack to wrap around the channel layers and the cap layer of the active region;
polishing the gate stack at least until the cap layer of the active region is exposed; and
forming a contact plug on the source/drain feature.

2. The method for forming the semiconductor structure as claimed in claim 1,
wherein a thickness of the cap layer is less than a thickness of one of the channel layers.

3. The method for forming the semiconductor structure as claimed in claim 1,
wherein the cap layer is made of a dielectric material.

4. The method for forming the semiconductor structure as claimed in claim 1, wherein:
the gate stack includes a gate dielectric layer and a gate electrode layer formed on the gate dielectric layer,
a topmost one of the channel layers is a first channel layer, and
the gate electrode layer is divided into an outer gate electrode outside the active region and a first inner gate electrode between the first channel layer and the cap layer.

5. The method for forming the semiconductor structure as claimed in claim 4, wherein polishing the gate stack is completed when the first inner gate electrode is exposed.

6. The method for forming the semiconductor structure as claimed in claim 4, wherein polishing the gate stack is completed when a portion of the gate dielectric layer between the cap layer and the first inner gate electrode is exposed.

7. The method for forming the semiconductor structure as claimed in claim 1, further comprising:
forming an etching stop layer over the gate stack;
forming a first dielectric layer over the etching stop layer, wherein the contact plug is formed through the first dielectric layer and the etching stop layer; and
polishing the first dielectric layer and the contact plug to expose the etching stop layer.

8. The method for forming the semiconductor structure as claimed in claim 7, further comprising:
polishing the etching stop layer to expose the gate stack.

9. The method for forming the semiconductor structure as claimed in claim 7, further comprising:
forming a second dielectric layer over the contact plug; and
forming a via on the gate stack.

10. The method for forming the semiconductor structure as claimed in claim 9, wherein the via lands on the contact plug, wherein the via has a first bottom surface that interfaces with the contact plug and a second bottom surface that interfaces with the gate stack, and the first bottom surface is higher than the second bottom surface.

11. A method for forming a semiconductor structure, comprising:
forming a stack of alternating first semiconductor layers and second semiconductor layers on the substrate;
forming a dielectric layer on the stack;
patterning the dielectric layer, the stack and the substrate into the active region;
replacing the first semiconductor layers of the active region with dielectric interposers;
removing the dielectric interposers;
forming a gate electrode layer to surround the dielectric layer and the second semiconductor layers of the active region; and
removing the gate electrode layer and the dielectric layer of the active region.

12. The method for forming the semiconductor structure as claimed in claim 11, further comprising:
etching the active region to form a recess;
forming a dielectric isolation layer in the recess;
forming a source/drain feature on the dielectric isolation layer in the recess; and
forming a contact plug partially embedded in the source/drain feature, wherein a bottom surface of the contact plug is lower than a bottom surface of a topmost one of the second semiconductor layers.

13. The method for forming the semiconductor structure as claimed in claim 12, wherein the contact plug is in direct contact with the dielectric isolation layer.

14. The method for forming the semiconductor structure as claimed in claim 10, further comprising:
forming an isolation structure to surround a lower portion of the active region;
cutting the gate electrode layer into a first segment and a second segment; and
forming a first via and a second via on the gate electrode layer, wherein the first via overlaps the active region, the second via overlaps the isolation structure, and in a vertical direction, the first via is shorter than the second via.

15. A semiconductor structure, comprising:
a plurality of nanostructures;
a source/drain feature adjoining the nanostructures;
a gate dielectric layer surrounding the nanostructures; and
a gate electrode layer on the gate dielectric layer and extending in a first horizontal direction, wherein:
the gate electrode layer is divided into a first inner gate electrode above the plurality of nanostructures and a second inner gate electrode between adjacent two of the nanostructures,
the first inner gate electrode includes a first metal material and a second metal material, and
in a cross-sectional view, the first metal material surrounds four sides of the second metal material.

16. The semiconductor structure as claimed in claim 15, further comprising:
an etching stop layer over the gate electrode layer; and
a contact plug through the etching stop layer and in the source/drain feature, wherein the contact plug has a first dimension measured from a top surface of the first inner gate electrode to a top surface of the contact plug in a vertical direction and a second dimension measured from the top surface of the first inner gate electrode to a bottom surface of the contact plug in a vertical direction, and the first dimension of the contact plug is less than the second dimension of the contact plug.

17. The semiconductor structure as claimed in claim 16, wherein the etching stop layer is in direct contact with the top surface of the first inner gate electrode, and a top surface of the first etching stop layer is level with the top surface of the contact plug.

18. The semiconductor structure as claimed in claim 15, further comprising:
a dielectric layer above the plurality of nanostructures, wherein in a cross-sectional view, the gate electrode layer surrounds three sides of the dielectric layer.

19. The semiconductor structure as claimed in claim 18, further comprising:
a via penetrating through the dielectric layer and extending into the first inner gate electrode.

20. The semiconductor structure as claimed in claim 15, wherein the gate dielectric layer includes a portion extending along a top surface of the first inner gate electrode.
